(19) United States
(12) Patent Application Publication
(10) Pub. No.: US 2008/0241988 A1
(43) Pub. Date: Oct. 2, 2008

(54) METHOD FOR FABRICATING A SILICON SOLAR CELL STRUCTURE HAVING A GALLIUM DOPED P-SILICON SUBSTRATE

(75) Inventors: Ajeet Rohatgi, Marietta, GA (US); Abasifreke Ebong, Marietta, GA (US); Vijay Yelundur, Woodstock, GA (US)

Correspondence Address: ALSTON & BIRD LLP, BANK OF AMERICA PLAZA, 101 SOUTH TRYON STREET, SUITE 4000, CHARLOTTE, NC, 28280-4000, US

(73) Assignee: Georgia Tech Research Corporation, Atlanta, GA (US)

(21) Appl. No.: 12/138,179

(22) Filed: Jun. 12, 2008

Related U.S. Application Data
(62) Division of application No. 11/126,636, filed on May 11, 2005.
(60) Provisional application No. 60/569,899, filed on May 11, 2004.

(51) Int. Cl. H01L 31/18

(52) U.S. Cl. 438/93; 257/E31.025

(57) ABSTRACT

Devices, solar cell structures, and methods of fabrication thereof, are disclosed.

### CROSS-REFERENCE TO RELATED APPLICATIONS

This application is a Divisional of U.S. application Ser. No. 11/126,636, filed May 11, 2005, claiming priority to co-pending U.S. provisional application entitled, “Silicon Solar Cells,” having Ser. No. 60/569,899, filed May 11, 2004 which is hereby incorporated herein in its entirety by reference.

### TECHNICAL FIELD OF THE INVENTION(S)

The present disclosure is generally related to solar cells and, more particularly, embodiments of the present disclosure are related to silicon solar cells and methods of fabricating of silicon solar cells.

### BACKGROUND OF THE INVENTION

For many years, effort has been made to utilize the energy from the sun to produce electricity. On a clear day the sun provides approximately one thousand watts of energy per square meter almost everywhere on the planet's surface. The historical intention has been to collect this energy by using, for example, an appropriate solar semiconductor device. The collected energy is used to produce power by the creation of a suitable voltage and to maximize amperage, which is represented by the flow of electrons. However, to date, many photovoltaic or solar cells typically have low overall efficiency.

The success of the solar cell industry has been impeded due to this lack of efficiency in solar cell fabrication and usage. For example, it is relatively expensive to manufacture the semiconductor materials currently utilized for solar cells and applicable processes. One traditional approach for manufacturing solar cells has included converting low quality silicon wafers from the semiconductor industry into solar cells by known techniques for treating low quality solar cells, which include etching of the wafers and subsequent processing of the silicon wafers so that they can function as solar cells. A second technique includes creating relatively thin layers of crystalline and/or amorphous silicon upon an appropriate substrate followed by processing techniques, which ultimately result in the production of a solar cell/solar panel. However, the extensive processes used in the above described approaches have historically been relatively inefficient, making the solar cell industry less than ideal.

Thus, a heretofore unaddressed need exists in the solar cell industry for solar cells and processes for fabricating the solar cells that address the aforementioned deficiencies and/or inadequacies.

### BRIEF SUMMARY OF THE INVENTION

Devices, solar cell structures, and methods of fabrication thereof, are disclosed. Briefly described, one exemplary embodiment of the device, among others, includes: a p-type gallium doped silicon substrate having a top-side and a back-side, wherein the bulk lifetime is about 20 to 2500 μs; an n⁺ layer formed on the top-side of the p-type gallium doped silicon substrate; a silicon nitride anti-reflective (AR) layer positioned on the top-side of the n⁺ layer; a plurality of Ag contacts positioned on portions of the silicon nitride AR layer, wherein the Ag contacts are in electronic communication with the n⁺ layer; a uniform Al back-surface field (BSF) layer having a top-side and a back-side, the top-side of the Al BSF layer being positioned on the back-side of the Ga doped p-silicon substrate; and an Al contact layer positioned on the back-side of the Al BSF layer, wherein the device has a fill factor (FF) of about 0.75 to 0.85, an open circuit voltage (V_{oc}) of about 600 to 650 mV, and a short circuit current density (J_{sc}) of about 28 to 36 mA/cm².

Briefly described, another exemplary embodiment of the device, among others, includes: a p-type silicon substrate having a top-side and a back-side, wherein the bulk lifetime is about 20 to 2500 μs; an n⁺ layer formed on the top-side of the p-type silicon substrate; a silicon nitride AR layer positioned on the top-side of the n⁺ layer; a plurality of Ag contacts positioned on portions of the silicon nitride AR layer, wherein the Ag contacts are in electronic communication with the n⁺ layer; a silicon nitride layer disposed on the back-side of the p-type silicon substrate; a fired screened printed aluminum grid, wherein the aluminum grid includes a plurality of aluminum contacts that are fired through the silicon nitride layer, wherein the aluminum contacts are in electrical communication with the p-type silicon substrate; and a uniform Al BSF layer disposed between the aluminum contact and the p-type silicon substrate, wherein the device has a FF of about 0.75 to 0.85, a Voc of about 600 to 650 mV, and a Jsc of about 28 to 36 mA/cm².

Briefly described, another exemplary embodiment of the device, among others, includes: a p-type silicon substrate having a top-side and a back-side, wherein the bulk lifetime is about 20 to 2500 μs; an n⁺ layer formed on the top-side of the p-type silicon substrate; a silicon nitride AR layer positioned on the top-side of the n⁺ layer; a plurality of Ag contacts positioned on portions of the silicon nitride AR layer, wherein the Ag contacts are in electronic communication with the n⁺ layer; an i-type amorphous silicon layer having a front-side and a back-side, wherein the front-side of the i-type amorphous silicon layer is disposed on the back-side of the p-type silicon substrate; a p-type amorphous silicon layer having a front-side and a back-side, wherein the front-side of the p-type amorphous silicon layer is disposed on the back-side of the i-type amorphous silicon substrate; and a transparent conducting oxide layer having a front-side and a back-side, wherein the transparent conducting oxide layer is disposed on the back-side of the p-type amorphous silicon layer; wherein the device has a FF of about 0.75 to 0.85, an Voc of about 600 to 650 mV, and a Jsc of about 28 to 36 mA/cm².

Briefly described, one exemplary embodiment of a method for fabricating a silicon solar cell stricture includes: providing a gallium doped p-silicon substrate having a top-side and a back-side; forming a n⁺ layer on the top-side of the gallium doped p-silicon substrate; forming a silicon nitride AR layer on the top-side of the n⁺ layer; forming Ag contacts on the silicon nitride AR layer using a screen-printing technique; forming an Al contact layer on the back-side of the gallium doped p-silicon substrate using a screen-printing technique; co-firing of the gallium doped p-silicon substrate having the n⁺ layer, silicon nitride AR layer, Ag metal contacts, and Al contact layer; and forming a co-fired silicon solar cell structure, wherein the Ag contacts are in electrical communication with the n⁺ layer, wherein an Al BSF is formed, and wherein the silicon solar cell has a fill factor of about 0.75 to 0.85, a Voc of about 550 to 650 mV, and a Jsc of about 28 to 36 mA/cm².

Briefly described, another exemplary embodiment of a method for fabricating a silicon solar cell structure includes: providing a p-silicon substrate having a top-side and a back-side; forming a n⁺ layer on the top-side of the p-silicon substrate; forming a silicon nitride AR layer on the top-side of the n⁺ layer; forming Ag contacts on the silicon nitride AR layer using a screen-printing technique; forming a silicon nitride layer disposed on the back-side of the p-type silicon substrate; forming an aluminum grid on the back-side of the silicon nitride layer using a screen-printing technique, wherein the aluminum grid includes a plurality of aluminum contacts; co-firing of the p-silicon substrate having the n⁺ layer, silicon nitride AR layer, Ag metal contacts, aluminum grid, and silicon nitride layer; and forming a co-fired silicon solar cell structure, wherein the Ag contacts are in electrical communication with the n⁺ layer, wherein the aluminum contacts that are fired through the silicon nitride layer, wherein an Al BSF is formed, and wherein the silicon solar cell has a fill factor of about 0.75 to 0.85, a Voc of about 550 to 650 mV, and a Jsc of about 28 to 36 mA/cm².

Briefly described, another exemplary embodiment of a method for fabricating a silicon solar cell structure includes: providing a p-silicon substrate having a top-side and a back-side; forming a n⁺ layer on the top-side of the p-silicon substrate; forming a silicon nitride AR layer on the top-side of the n⁺ layer; forming a silicon nitride layer on the backside of p-silicon; forming Ag contacts on the silicon nitride AR layer using a screen-printing technique; firing the Ag contacts; removing the silicon nitride layer removal from the backside of p-silicon substrate; forming an i-type amorphous silicon layer on the back-side of the co-fired p-type silicon substrate, wherein the i-type amorphous silicon layer has a front-side and a back-side; forming a p-type amorphous silicon layer on the back-side of the i-type amorphous silicon substrate, the p-type amorphous silicon layer has a front-side and a back-side; forming a transparent conducting oxide layer on the back-side of the p-type amorphous silicon layer, the transparent conducting oxide layer has a front-side and a back-side; forming the Al contacts on the backside of the transparent conducting oxide layer using a low temperature firing of the p-silicon substrate; and forming a two-step fired silicon solar cell structure, wherein the Ag contacts are in electrical communication with the n⁺ layer, and wherein the silicon solar cell has a fill factor of about 0.75 to 0.85, a Voc of about 550 to 650 mV, and a Jsc of about 28 to 36 mA/cm².

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims.

### BRIEF DESCRIPTION OF THE DRAWING(S)

Many aspects of the disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIG. 1 illustrates an exemplary embodiment of a silicon solar cell structure.

FIG. 2 illustrates a flowchart describing an exemplary method of forming the silicon solar cell structure shown in FIG. 1.

FIGS. 3A through 3F illustrate an exemplary method of forming the silicon solar cell structure shown in FIG. 1.

FIG. 4 illustrates an exemplary embodiment of a silicon solar cell structure.

FIG. 5 illustrates a flowchart describing a representational method of the fabrication process for the silicon solar cell structure shown in FIG. 4.

FIGS. 6A through 6C are schematics that illustrate an exemplary method of forming the silicon solar cell structure shown in FIG. 4.

FIG. 7 illustrates an exemplary embodiment of a screen-printed contact co-fired silicon solar cell structure.

FIGS. 8A through 8C are schematics that illustrate an exemplary method of forming the silicon solar cell structure shown in FIG. 7.

FIG. 9 illustrates an exemplary embodiment of a screen-printed contact two-step fired silicon solar cell structure.

FIG. 10 illustrates a flowchart describing a representational method of the fabrication process for the fired silicon solar cell structure shown in FIG. 9.

FIGS. 11A through 11D are schematics that illustrate an exemplary method of forming the fired silicon solar cell structure shown in FIG. 9.

FIGS. 12A and 12B illustrate as-grown (12A) and post-diffusion (12B) lifetime before and after LID on wafers from different locations in the low and high resistivity B-doped Cz ingot.

FIG. 13 illustrates a normalized metastable defect concentration before and after diffusion process in B-doped Cz wafers.

FIGS. 14A and 14B illustrate as-grown (14A) and post-diffusion (14B) lifetime before and after LID on wafers from different locations in Ga-doped Cz ingot.

FIG. 15 illustrates screen-printed Al-BSF solar cells efficiency of samples from different locations from low- and high-resistivity B-doped Cz ingots.

FIG. 16 illustrates simulated solar cell efficiency as a function of lifetime for a) 1.0 Ω-cm 300 μm thick Si substrate and b) 4.3 Ω-cm 230 μm thick Si substrate. The simulated curves are used to show the predicted cells efficiencies based on measured lifetime (1) before LID (2) after LID but at injection level of 2×10¹⁴ and (3) after LID at an injection level at MPP.

FIG. 17 illustrates a measured bulk lifetime as a function of injection level, before and after LID, for ˜1 Ω-cm and ˜4.3 Ω-cm B-doped Cz.

FIG. 18 illustrates a screen-printed Al-BSF solar cells efficiency of samples from different locations from Ga-doped Cz ingot.

FIG. 19 illustrates a graph of J_{sc} and V_{oc} as a function of ingot position in Ga-doped ingot.

### DETAILED DESCRIPTION OF THE INVENTION

In accordance with the purposes(s) of the present disclosure, as embodied and broadly described herein, embodiments of the present disclosure, in one aspect, relate to silicon solar cell structures and methods of fabricating silicon solar cell structure.

In one embodiment of the silicon (Si) solar cell structure includes, but is not limited to, a gallium (Ga) doped p-silicon substrate, a n⁺-type emitter layer formed on the top-side (i.e., top, front, and front-side of the Ga doped p-silicon substrate) of the Ga doped p-silicon substrate, a silicon nitride (e.g., SiNₓ) antireflection (AR) layer positioned on the top-side of the n⁺-type emitter layer, a plurality of silver (Ag) contacts (which are part of an Ag grid) positioned on portions of the SiNₓ antireflective layer, an aluminum (Al) back-surface field (BSF) layer positioned on the back-side (i.e., back, rear, and rear-side of the Ga doped p-silicon substrate) of the Ga doped p-silicon substrate (i.e., the side opposite the n⁺-type emitter layer), and an Al contact layer positioned on the back-side of the Al BSF. The Ag contacts are electronically connected to the n⁺-type emitter layer.

In another embodiment of the Si solar cell structure includes, but is not limited to, a p-silicon substrate, a n⁺-type emitter layer formed on the top-side (i.e., top, front, and front-side of the p-silicon substrate) of the p-silicon substrate, a SiNₓ AR layer positioned on the top-side of the n⁺-type emitter layer, a plurality of Ag contacts (which are part of an Ag grid) positioned on portions of the SiNₓ AR layer, a SiNₓ layer disposed on the back-side of the p-silicon substrate, a fired screen printed Al grid disposed on the back-side of the SiNₓ layer, where the fired screen printed Al grid includes Al contacts in electrical communication with the p-silicon substrate, and a BSF layer positioned between the back-side (i.e., back, rear, and rear-side of the p-silicon substrate) of the p-silicon substrate (i.e., the side opposite the n⁺-type emitter layer) and the Al contacts. The Ag contacts are electronically connected to the n⁺-type emitter layer. In another embodiment, the p-silicon substrate can be a Ga doped p-silicon substrate.

In still another embodiment of the Si solar cell structure includes, but is not limited to, a p-silicon substrate, a n⁺-type emitter layer formed on the top-side of the p-silicon substrate, a SiNₓ AR layer positioned on the top-side of the n⁺-type emitter layer, a plurality of Ag contacts (which are part of an Ag grid) positioned on portions of the SiNₓ AR layer, an intrinsic amorphous silicon (i-α-Si:H) layer disposed on the back-side of the co-fired p-type silicon substrate; a p-type amorphous silicon layer disposed on the back-side of the (i-α-Si:H), and a transparent conducting oxide layer (e.g., indium tin oxide) disposed on the back-side of the p-type amorphous silicon layer. The Ag contacts are electronically connected to the n⁺-type emitter layer. In another embodiment, the p-silicon substrate can be a Ga doped p-silicon substrate.

In general, embodiments of the fabrication of silicon solar cell structure include processes that result in a silicon solar cell structure having one or more unexpected characteristics such as, but not limited to, substantially reduced or substantially eliminated light induced degradation as compared to B-doped p-silicon with high oxygen concentration grown by Czochralski method (e.g., absence of B—O pair), superior ohmic contact, superior solar cell performance and efficiency, and superior Al BSF, as compared with other solar cells.

In particular, embodiments of the silicon solar cell structure have one or more unexpected characteristics, as compared with other solar cells, such as, but not limited to, superior resistance to LID, superior bulk lifetimes, superior fill factor (FF), superior open circuit voltage (Voc), and superior short circuit current density (Jsc). In addition, embodiments of the silicon solar cell structure may have one or more additional characteristics such as, but not limited to, superior blue response, superior series resistance (Rs), superior shunt resistance, superior junction leakage current density (J_{O2}), superior bulk lifetime, superior back-surface field, superior emitter saturation current density (Jₒₑ), superior base saturation current density (J_{ob}), superior grid design, gridline width, and gridline shrinkage, and final metal gridline resistivity.

The silicon solar cell structure can be used, individually or in combination, in solar cell modules. The silicon solar cell modules incorporating one or more silicon solar cell structures can be used in many areas such as, but not limited to, orbiting space satellites, remote telecommunication repeaters, fiber optic amplifiers, remote street signs, telephone booths, outdoor lighting, homes, businesses, utility scale power generation, and the like.

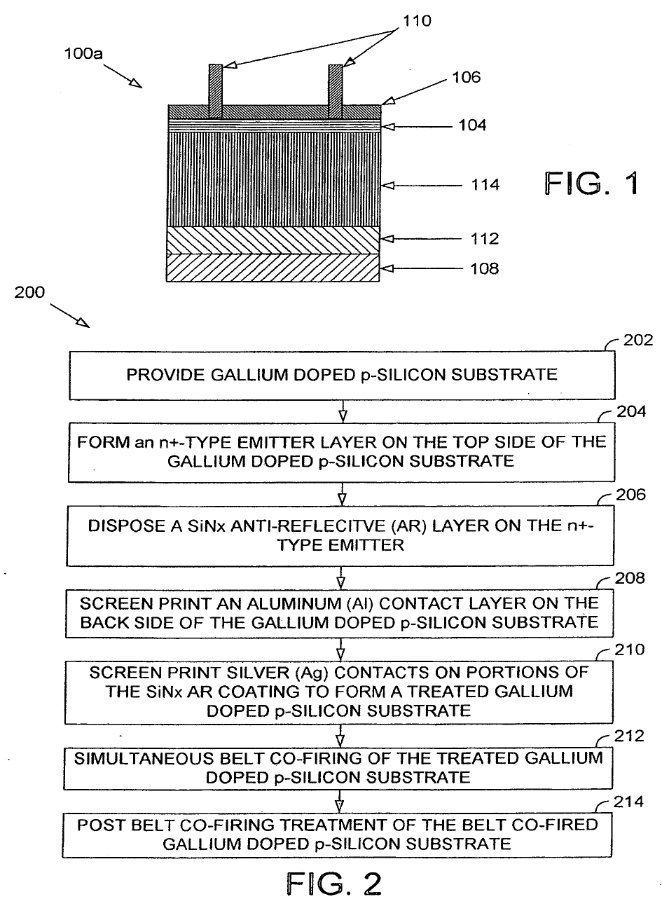

Now having described embodiments of the silicon solar cell structure and methods of making the silicon solar cell structure in general, the following figures and the accompanying text describe various embodiments in greater detail. FIGS. 1, 4, 7, and 9 illustrate embodiments of the silicon solar cell structures.

FIG. 1 illustrates an exemplary embodiment of a screen-printed contact co-fired gallium (Ga) doped silicon solar cell structure 100a (e.g, after co-firing of the metal screen-printed metal contacts process) (hereinafter “co-fired Ga doped silicon solar cell structure 100a”). The co-fired Ga doped silicon solar cell structure 100a includes, but is not limited to, a treated Ga doped p-silicon substrate 114 having a top-side and a back-side, a n⁺-type emitter layer 104 formed on the top-side of the treated Ga doped p-silicon substrate 114, a SiNₓ AR layer 106 positioned on the top-side of the n⁺-type emitter layer 104, a plurality of Ag contacts 110 (part of the Ag grid, where only the Ag contacts are shown) positioned on portions of the SiNₓ AR coating 106, an Al back-surface field layer 112 (formed after the metal co-firing process) positioned on the back-side of the treated Ga doped p-silicon substrate 114, and an Al contact layer 108 positioned on the back-side of the Al back-surface field layer 112. The term “plurality-as used herein can be consulted to mean two or more, as well as a multitude or numerous.

The Ga doped p-silicon substrate can include, but is not limited to, edge-defined film fed grown (EFG) silicon wafer, string ribbon silicon, float zone (FZ) silicon, Czochralski (Cz) grown silicon, and cast multi-crystalline silicon (mc-Si). Due to the treatment processes described herein, the Ga doped p-silicon substrate initially used (not shown in FIG. 1) can be of lower quality. In particular, the Ga doped p-silicon substrate is a Ga doped Cz silicon substrate. In one embodiment, the Ga doped p-silicon substrate has a resistivity of about 0.5 to 5 Ω-cm, about 0.5 to 4 Ω-cm, about 0.5 to 3 Ω-cm, and about 0.5 to 2.5 Ω-cm. The Ga doped p-silicon substrate can have a thickness of about 450 to 650 μm, about 350 to 500 μm, about 150 to 300 μm, and about 80 to 100 μm.

The process of forming the n⁺-type emitter layer 104, which is known as gettering, and metal contact co-firing involve diffusion of hydrogen from the SiNₓ into the Ga doped p-silicon substrate to passivate the defects sites (e.g., hydrogenation). A combination of these processes, in part, improves the quality of low quality Ga doped p-silicon substrate materials (e.g., materials having lifetime of about 0.5 μs). However, good quality Ga doped p-silicon substrate materials (e.g., materials having lifetimes of more than about 150 μs) may not benefit from the hydrogenation.

The n⁺-type emitter layer 104 can include, but is not limited to, about 55 to 120 Ω/sq, about 60 to 120 Ω/sq, about 65 to 120 Ω/sq, about 70 to 120 Ω/sq, about 75 to 120 Ω/sq, about 80 to 120 Ω/sq, about 85 to 120 Ω/sq, about 90 to 120 Ω/sq, about 95 to 120 Ω/sq, about 100 to 120 Ω/sq, about 105 to 120 Ω/sq, about 110 to 120 Ω/sq, about 115 to 120 Ω/sq, 55 to 100 Ω/sq, about 60 to 100 Ω/sq, about 65 to 100 Ω/sq, about 70 to 100 Ω/sq, about 75 to 100 Ω/sq, about 80 to 100 Ω/sq, about 85 to 100 Ω/sq, about 90 to 100 Ω/sq, and about 95 to 100 Ω/sq sheet resistance. In particular, the n⁺-type emitter layer can include, but is not limited to, about 55 Ω/sq, about 60 Ω/sq emitter, about 65 Ω/sq, about 70 Ω/sq, about 75 Ω/sq, about 80 Ω/sq emitter, about 85 Ω/sq, about 90 Ω/sq, about 95 Ω/sq, or about 100 Ω/sq emitter sheet resistance. The n⁺-type emitter layer can have a thickness of about 0.2 μm to 0.7 μm and about 0.31 μm to 0.5 μm.

The SiNₓ AR layer 106 can be described as a film, coating, or layer. Although, the stoichiometry of the SiNₓ is not fully understood, an estimate of the value of “x” can be from about 2 to 5. The SiNₓ AR layer 106 can have a thickness of about 700 to 850 Å, about 750 to 850 Å, and about 780 to 800 Å.

The Al contact layer 108 can have a thickness of about 50 to 60 μm, about 30 to 50 μm, and about 15 to 20 μm. It should be noted that the Al contact layer 108 thickness depends, at least in part, on the thickness of the Ga doped p-silicon substrate used. It also should be noted that a thicker Al contact layer 108 can cause warping of thin Ga doped p-silicon substrates, which can be detrimental to module assembly and the like.

The Al back-surface field layer 112 should have a uniform BSF, which can be accomplished using the co-firing process described herein. The Al back-surface field layer 112 can have a thickness of about 2 μm to 40 μm, about 2 μm to 30 μm, about 2 μm to 20 μm, about 2 μm to 15 μm, about 2 μm to 1 μm, or about 5 μm to 10 μm.

Further, the co-fired silicon solar cell structure 100a can include characteristics such as, but not limited to, a bulk lifetime of about 10 to 2500 μs, about 50 to 2500 μs, about 75 to 2500 μs, or about 100 to 2500 μs. The co-fired silicon solar cell structure 100a can include a series resistance (Rs) of about 0.01 to 1 Ω-cm², about 0.50 to 1 Ω-cm², or about 0.80 to 1 Ω-cm². The co-fired silicon solar structure 100a can include a shunt resistance of about 1000 to 5000 kΩ-cm², about 1000 to 3500 kΩ-cm², or about 1000 to 2000 kΩ-cm². The co-fired silicon solar cell structure 100a can include a junction leakage current density (J₀₂) of about 1 to 10 nA/cm², about 4 to 10 nA/cm², or about 7 to 10 nA/cm². The co-fired silicon solar cell structure 100a can include a contact resistance (ρc) of 0.01 to 3 mΩ-cm², about 1 to 3 mΩ-c cm², or about 1.5 to 3 mΩ-cm². The co-fired silicon solar cell structure 100a can include a back surface recombination velocity (BSRV) of about 50 to 1000 cm/s, about 400 to 1000 cm/s, or about 600 to 900 cm/s, but is should be noted this depends, in part, on the substrate resistivity.

It should be noted that the FF of the co-fired silicon solar cell structure 100a is related, at least in part, to the series resistance (Rs), the shunt resistance, and the junction leakage current density (J₀₂). In an embodiment, after co-firing, the co-fired silicon solar cell structure 100a has a Rs of about 0.80 to 1 Ω-cm², a shunt resistance of about 1000 to 2000 kΩ, and a J₀₂ of about 7 to 10 nA/cm², which indicate excellent ohmic contact and thus an excellent FF of 0.78 to 0.81. The co-firing process results in a co-fired silicon solar cell structure 100a with a reduction in junction leakage current, and a decrease in junction leakage current produces increased Jsc and an increased Voc. Unexpected silicon solar cell structure 100a characteristics are a result of the co-firing process described herein. For example, hydrogen is transferred from the SiNₓ AR layer 104 to the Ga doped p-silicon substrate 114 where it is retained in the defects (a process called defect passivation) of the solar cell structure 100a. It should be noted that deviation (e.g., longer holding times) from the co-firing process can drive the hydrogen out of the Ga doped p-silicon substrate 114, therefore, appropriate selection of process parameters can enhance the characteristics of the silicon solar cell structure 100a. In this regard, increased defect passivation results in a co-fired silicon solar cell structure 100a with increased bulk lifetime and increased solar cell efficiency. In another example, the co-fired silicon solar cell structure 100a also includes an Al back surface field with increased uniformity due, at least in part, to uniform surface wetting with fast ramp-up. It should also be noted, that the excellent BSRV obtained is due, at least in part, to a uniform Al back-surface field layer.

In one embodiment, among others, the co-fired silicon solar cell structure 100a can have characteristics such as, but not limited to, a fill factor (FF) of about 0.78 to 0.81, an open circuit voltage (Voc) of about 640 to 650 mV, and a short circuit current density (Jsc) of about 34 to 36 mA/cm². Further, the silicon solar cell structure 100a can include a bulk lifetime of 100 to 1000 μs, a series resistance (Rs) of about 0.5 to 1 Ω-cm², a shunt resistance of about 1000 to 2000 kΩ, a junction leakage current density (J₀₂) of about 7 to 10 nA/cm², and a back surface recombination velocity (BSRV) of about 50 to 900 cm/s.

In general, the silicon solar cell structure 100a, prior to co-firing, can be introduced to a belt furnace. For clarity, not every step in the process is shown, but one skilled in the art would understand additional steps that may need to be performed. In addition, the steps involved in the process can be performed in different orders, but in general, a Ga doped p-silicon (p-Si) substrate 114 is provided. An n⁺-type emitter layer 104 is formed on the top-side of the Ga doped p-silicon substrate 114. Then, a SiNₓ AR 106 layer is positioned on the top-side of the n⁺-type emitter layer 104. Next, an Al contact layer 108 is screen printed on the back-side of the Ga doped p-silicon substrate 114 using an Al paste and dried at a temperature (e.g., about 190 to 220° C.). Subsequently, an Ag contact 110 (e.g., part of an Ag metal grid (not shown)) is screen-printed on the top-side of the SiNₓ anti-reflective (AR) layer 106 using an Ag paste (e.g., PV168 and CN33-455Ag paste) and is dried at a temperature (e.g., about 190 to 220° C.). After the Ag contacts 110 and Al contact layer 112 are formed, the structure is subjected to a co-firing process in the belt furnace under conditions described in more detail below, but include a temperature ramp up stage, a temperature holding stage, and a temperature ramp down stage. Post co-firing treatments can also be conducted to complete the silicon solar cell formation process.

FIG. 2 illustrates a flowchart 200 describing a representational method of the fabrication process for the silicon solar cell structure 100a shown in FIG. 1. In Block 202 an untreated Ga doped p-silicon substrate having a top-side and a back-side is provided. The Ga doped p-silicon substrate can include substrates such as, but not limited to, a Ga doped Si wafer, EFG Ga doped Si ribbon, string Ga doped Si ribbon, FZ Ga doped Si, Cz Ga doped Si, or cast Ga doped mc-Si.

In Block 204, a n⁺-type emitter layer is formed on the top-side of the Ga doped p-silicon substrate. The n⁺-type emitter can include n⁺-type emitters as described above. In forming the n⁺-type emitter layer, the Ga doped p-silicon substrate samples can be cleaned and diffused using a liquid POCl₃ source in a tube furnace, for example. Spin-on, print-on, and spray-on phosphorus as well as and drive-in (at set temperatures depending on the required emitter sheet resistances) in a belt-furnace, a RTP, or a tube furnace.

In Block 206, a SiNₓ AR layer is positioned on the n⁺-type emitter. This process includes, but is not limited to, a pretreatment of ammonia plasma in-situ followed by the positioning of a low frequency (e.g., about 50 to 100 kHz) SiNₓ AR layer at about 400 to 450° C. in a direct plasma enhanced chemical vapor deposition (PECVD) SiNₓ reactor at about 750 to 800 A. Further, NH₃ and SiH₄ gases are present in the PECVD reactor and react to form the SiNₓ AR layer. Additional methods include direct PECVD (13.6 MHz) or remote PECVD (2.45 GHz) performed at temperatures between 350-450° C., for example. As a result, a large source of atomic hydrogen is created not only in the SiNₓ layer but also in a very thin Si layer underneath the SiNₓ AR layer. This is a result of high-energy ion bombardment, due to the low frequency SiNₓ positioning. In another embodiment, another material (e.g., MgF) can also be used to coat the SiNₓ AR layer to form a double layer AR coating.

In Block 208, Al contacts are screen-printed on the back-side of the Ga doped p-silicon substrate. The Al contact can be positioned using, but not limited to, an Al paste which can be disposed using techniques such as, but not limited to, a process in which Al paste is screen printed on the back of the Ga doped p-silicon substrate and dried at about 190 to 220° C. to form the Al contact layer on the back-side of the Ga doped p-silicon substrate. The Al paste can include, but is not limited to FX53-038, FX53-100, and FX53-101.

In Block 210, Ag contacts are positioned on portions of the SiNₓ AR layer using an Ag paste such as, but not limited to, PV168 paste (produced by DuPont) Ferro CN33-455, CN33-460, CN33-455, and CN33-462. The Ag contact can be positioned using techniques such as, but not limited to, a process in which Ag paste is screen-printed on the top-side of the SiNₓ AR layer. It should also be noted that photolithography and laser grooved techniques can be used to provide front metal contacts to silicon solar cells.

In Block 212, a rapid belt co-firing process can be used to treat the silicon solar cell structure 100a. The co-firing process occurs after the positioning of the above described elements including, but not limited to, the Ga doped p-silicon substrate, the n⁺-type emitter on the top-side of the Ga doped p-silicon substrate, the SiNₓ AR layer on the top-side of the n⁺-type emitter, the Al contact on the back-side of the Ga doped p-silicon substrate, and/or the Ag contacts on the top-side of the SiNₓ AR layer.

The rapid co-firing process involves a simultaneous firing process. The co-firing process includes a temperature ramp up process. The ramp up process is performed at a ramp up rate of about 50 to 100° C./s, about 50 to 80° C./s, and about 50 to 60° C./s to reach the temperature of about 700 to 900° C., about 750 to 850° C., or about 740 to 780° C. Then, the co-firing process includes a temperature holding stage. In the temperature holding phase, the firing and hold time is about 1 to 5 seconds, about 1 to 3 seconds, or about 1 to 2 seconds, each at a temperature of about 700 to 900° C., about 750 to 850° C., or about 740 to 780° C. The shorter holding time results in maximum lifetime enhancement due to the higher retention of the hydrogen in the defect sites. Then, the co-firing process includes a ramp down stage. The ramp down stage includes reducing the temperature according to a ramp down rate of about 50 to 100° C./s, about 50 to 80° C./s, or about 50 to 60° C./s.

The rapid co-firing process is controlled, in part, by the belt speed and temperature setting in each zone of the belt furnace. The temperature in each zone or stage and the belt speed can each be set to achieve the temperature parameters described above. For example, the belt speed can be about 15 to 100 inches per minute (ipm), 50 to 100 ipm, 80 to 100 ipm, or 100 to 120 ipm.

Although not intending to be bound by theory, the co-firing process described above, and the way in which the process is conducted, provide unexpected results. For example, the co-firing temperature and time exposed to the temperature allow for the simultaneous formation of front Ag contacts and Al back-surface field (p⁺ layer). Specifically, the co-firing steps result in the formation of a uniform BSF (or p⁺ layer) on the back-side of the co-fired solar cell structure 114. The co-firing process results in the etching of the SiNₓ AR layer by the glass frit contained in the Ag contacts to form a contact with the n⁺-type emitter layer, which allows n⁺-type emitter layer of higher sheet resistance values to be used (as described above). Further, the co-firing process produces a solar cell structure with unexpected characteristics such as, but not limited to, an increased defect passivation (in low quality silicon substrates), which results in increased J_{sc}, increased V_{oc}, and increased FF. The co-firing process also results in a more uniform Al BSF and a decreased BSRV. These above-described variables result in an increased solar cell bulk lifetime and increased solar cell efficiency, which are unexpected and are obtained using the ramp up stage, hold stage, and ramp down stage, as described above.

In Block 214, post belt co-firing treatment can optionally be conducted. Following the co-firing event, the Ag contacts can be covered with photoresist, for example, to enable the edge isolation of the cells with the dicing saw and/or a photolithography process followed by etching in, for example, a buffered oxide etchant (BOE) to remove the shunting path. The most common approach is the isolation of the cells using dicing of each silicon wafers, without the use of photolithography and etching thereafter, followed by a forming gas annealing process at about 350 to 450° C. for a specified time of about 15 to 20 minutes, for example. It should also be noted that modifications to the process sequence could be performed to produce the silicon solar cell structure 100a as well.

As discussed above, the silicon solar cell structure 100a can be co-fired. In an embodiment, the co-firing process occurs in a three-zone lamp-heated belt furnace at specified belt speeds and temperatures to achieve certain ramp up stages, hold stages, and ramp down stages. For example, the belt furnace temperature can be ramped up at a rate of about, for example, 50 to 100° C./s, about 50 to 80° C./s, or about 50 to 60° C./s, as described above. The rate can be achieved, at least in part, by the belt speed, the temperature of the belt furnace, and the dimensions of the belt furnace. For example, the belt furnace can be held at a temperature of about, for example, 700 to 900° C., about 750 to 850° C., or about 740 to 780° C. for about 1 to 5 seconds, about 1 to 3 seconds, or about 1 to 2 seconds. For example, the belt furnace temperature can be ramped down at a rate of, for example, about 50 to 100° C./s, about 50 to 80° C./s, or about 50 to 60° C./s.

Although not intending to be bound by theory, the co-firing process drives the atomic hydrogen from the SiNₓ AR layer into the Si underneath on the Ga doped p-silicon substrate to passivate the defects in it, thus producing an improved bulk minority carrier lifetime. Thus, for example, a 1 second firing of SiNₓ/Al enhances processing throughput, bulk lifetime, and cell efficiency without sacrificing the Al-BSF quality. The improved BSF results from fast ramp up rates, very short hold time at about 740° C., for example, and fast ramp down rates, thus producing improved bulk lifetime by enhancing the retention of hydrogen at defects. This improvement is characterized by an increased lifetime from about 1 μs to 20-1000 μs or more, for example. The co-firing temperature allows for the simultaneous formation of Ag front side contacts and Al back-surface field (p⁺) and Al back contacts with the Ga doped p-silicon substrate using Ag paste and Al paste, respectively. Further, this process produces a back surface recombination velocity (BSRV) value of about 200 to 900 cm/s and solar cell fill factors (FF) of about 0.75-0.80, due to good ohmic contacts.

Good ohmic contacts can be characterized, in part, by contact resistance (ρc), series resistance (Rₛ) and junction leakage current density (J₀₂) values. The positioning of a low frequency Si₃N₄ film at about 400 to 450° C. provides surface passivation that lowers the surface recombination velocity (SRV) from about 250,000 cm/s to about 35,000-60,000 cm/s. Thus, resulting in a lower emitter saturation current (Jₒₑ) 400 to 90 pA/cm² and increased open circuit voltage (V_{oc}). For example, a co-firing event using PV168 Ag, CN33-455, and CN33-462 paste, providing good surface passivation gives about 1% higher cell efficiency with 1.96 mA/cm² higher short circuit current density (J_{sc}).

Current production of screen-printed cells in production are fabricated on about a 30 to 45 Ω/sq. emitter sheet resistance, resulting in poor surface passivation and blue response. The present disclosure describes processes that includes a lightly-doped emitter including greater than about 55 Ω/sq, about 60 Ω/sq, about 65 Ω/sq, about 70 Ω/sq, about 75 Ω/sq, about 80 Ω/sq, about 85 Ω/sq, about 90 Ω/sq, about 95 Ω/sq, or about 100 Ω/sq emitter sheet resistance, with good surface passivation and thus, an enhanced short circuit current density (J_{sc}) due to better blue response.

In one embodiment, an Ag paste (e.g., PV168 Ag paste that can be purchased from DuPont or CN33-455 or CN33-462 that is purchased from Ferro Corporation) is used. The PV168 Ag or CN33-455 or CN33-462 paste is constructed such that it etches through the SiNₓ layer without excessively etching the Si (emitter) underneath under the conditions of the co-firing process described herein. This allows for better contacts with the n⁺-type emitter and thus providing a lower Ag crystallite concentration near the junction. In this regard, having no crystallite shunting the junction, results in higher open circuit voltage (Voc) and higher fill factor (FF), and thus a higher efficiency solar cell. After screen-printing, the organic constituents in the pastes are then burnt-out during a burn-out step at a specified belt speed at about 20 to 30 ipm in the belt-furnace with sample temperature reaching about 350 to 450° C. The treated p-silicon substrate is then co-fired at high belt speeds of about 80 to 120 ipm at about 740° C. to 800° C., which is less than the melting point of Ag.

For the purposes of illustration only, the co-fired silicon solar cell structure 100a is described with particular reference to the below-described fabrication method. The fabrication method is described from the point of view shown in FIG. 1.

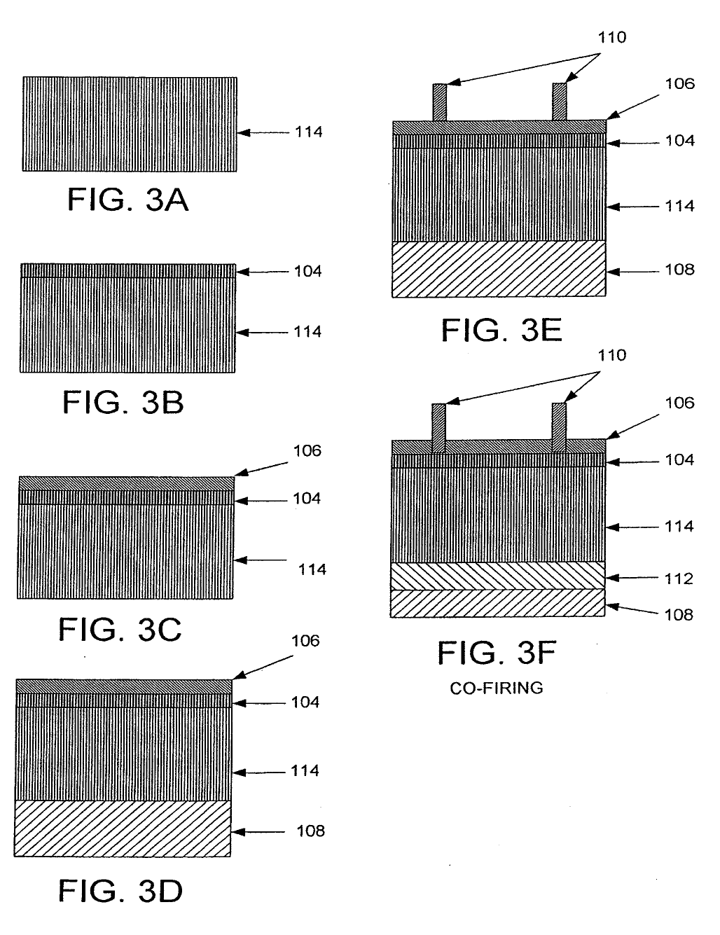

For clarity, some portions of the fabrication process are not included in FIGS. 3A through 3F. The following fabrication process is not intended to be an exhaustive list that includes every step in the fabrication of the co-fired silicon solar cell structure 100a. In addition, the fabrication process is flexible and the process steps may be performed in a different order than the order illustrated in FIGS. 3A through 3F.

In general, the silicon solar cell structure 100a can be formed in a manner described in FIGS. 3A through 3F. FIGS. 3A through 3F are schematics that illustrate an exemplary method of forming the silicon solar cell structure 100a shown in FIG. 1. FIG. 3A illustrates the Ga doped p-silicon substrate 114. FIG. 3B illustrates the formation of the n⁺-type emitter 104 formed on the top-side of the Ga doped p-silicon substrate 114. The n⁺-type emitter 104 can be formed using techniques such as, but not limited to, the RCA cleaning of the Ga doped p-silicon substrate 114 followed by POCl₃ diffusion to form the n⁺-type emitter 104.

FIG. 3C illustrates the positioning of a SiNₓ AR layer 106 on the top-side of the n⁺-type emitter layer 104. The SiNₓ AR layer 106 can be positioned using techniques such as, but not limited to, a plasma-enhanced chemical vapor deposition (PECVD) process.

FIG. 3D illustrates the positioning of an Al contact 108 on the back-side of the Ga doped p-silicon substrate 114. The Al contact layer 108 can be positioned using techniques such as, but not limited to, a process in which Al paste is screen-printed on the back-side of the Ga doped p-silicon substrate 114 and dried at a specified temperature.

FIG. 3E illustrates the positioning of Ag contacts 110 on the top-side of the SiNₓ AR layer 106. The Ag contacts 110 can be formed using techniques such as, but not limited to, screen-printing. FIG. 3F illustrates the co-fired silicon solar cell structure 100a after rapid co-firing.

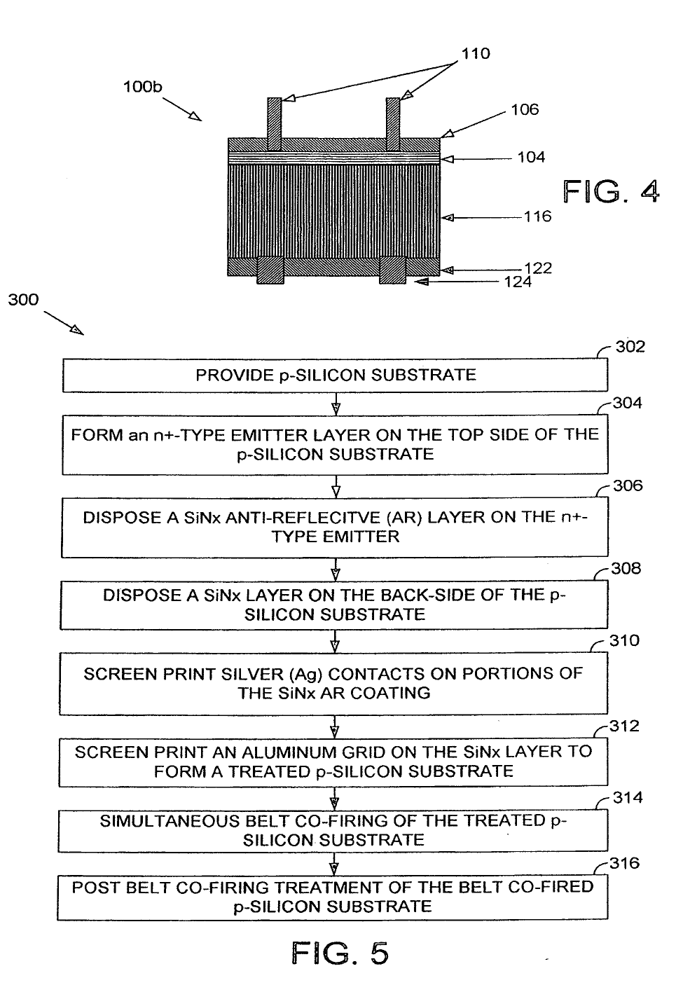

FIG. 4 illustrates an exemplary embodiment of a screen-printed contact co-fired silicon solar cell structure 100b (e.g., after co-firing of the metal screen-printed metal contacts process) (hereinafter “co-fired silicon solar cell structure 100b”). The co-fired silicon solar cell structure 100b includes, but is not limited to, a treated p-silicon substrate 116 having a top-side and a back-side, a n⁺-type emitter layer 104 formed on the top-side of the treated p-silicon substrate 116, a silicon nitride (SiNₓ) anti-reflective (AR) layer 106 positioned on the top-side of the n⁺-type emitter layer 104, a plurality of Ag contacts 110 (part of the Ag grid, where only the Ag contacts are shown) positioned on portions of the SiNₓ AR coating 106, a SiNₓ layer 122 (or in another embodiment, an SiO₂/SiNₓ stack) disposed on the back-side of the p-silicon substrate 116, a fired screened printed aluminum (Al) grid (only part of the Al grid is shown, where only the Al contacts 124 are shown) disposed on the back-side of the SiNₓ layer 122 (or in another embodiment, an SiO₂/SiNₓ stack), where the Al contacts 124 are in electrical communication with the p-silicon substrate 116, and a back-surface field (BSF) layer (not shown) positioned (underneath the Al contacts) between the back-side (i.e., back, rear, and rear-side of the p-silicon substrate 116) of the p-silicon substrate 116 (i.e., the side opposite the n⁺-type emitter layer) and the Al contacts 124. The Ag contacts 110 are electronically connected to the n⁺-type emitter layer. In another embodiment, the p-silicon substrate 116 can be a Ga doped p-silicon substrate such as that described above in reference to FIGS. 1 and 2 and the corresponding text.

The p-silicon substrate 116 can include, but is not limited to, edge-defined film fed grown (EFG) silicon wafer, string ribbon silicon, float zone (FZ) silicon, Czochralski (Cz) grown silicon, and cast multi-crystalline silicon (mc-Si). Due to the treatment processes described herein, the p-silicon 116 substrate initially used (not shown in FIG. 4) can be of lower quality. In particular, the p-silicon substrate is a Cz silicon substrate. In one embodiment, the p-silicon substrate 116 has a resistivity of about 0.5 to 5 Ω-cm, about 0.5 to 4 Ω-cm, about 0.5 to 3 Ω-cm, or about 0.5 to 2.5 Ω-cm. The p-silicon substrate can have a thickness of about 450 to 650 μm, about 350 to 500 μm, or about 150 to 300 μm.

The n⁺-type emitter layer 104, SiNₓ AR layer 104, and the Ag contacts 110, are similar to the layers described in reference to FIGS. 1 and 2 above.

The SiNₓ layer 122 disposed on the back-side of the p-silicon substrate 116 can be described as a film, a coating, or a layer. Although, the stoichiometry of the SiNₓ is not fully understood, an estimate of the value of “x” can be from about 2 to 5. The SiNₓ layer 122 (or in another embodiment, an SiO₂/SiNₓ stack) can have a thickness of about 250-850 Å, about 700 to 850 Å, about 750 to 850 Å, or about 780 to 800 Å.

The fired screened printed Al grid and the Al contacts 124 have a thickness of about 10-30 μm after printing. FIG. 4 illustrates two Al contacts 124, but three or more Al contacts can be used, depending on the size of the cell. The Al grid and Al contacts 124 can be made of aluminum Fx53-100, and other types of aluminum. In an embodiment, the Al is capable of firing through the silicon nitride at temperatures that are not high enough to destroy the bulk passivation. The Al grid and Al contacts 124 can be disposed on the SiNₓ layer 122 using techniques such as, but not limited to, screen printing, evaporation, and the like.

Upon co-firing, the Al contacts 124 are fired through the SiNₓ layer 122 and are subsequently in electrical communication with the p-silicon substrate 116. In addition, a uniform Al back-surface field (BSF) layer disposed between the Al contact 124 and the co-fired p-type silicon substrate 116. The thickness of the BSF layer after firing is about 5-20 μm.

As indicated above, the co-fired silicon solar cell structure 100b can have characteristics such as, but not limited to, a fill factor (FF) of about 0.75 to 0.85, about 0.78 to 0.83, and about 0.78 to 0.81. The co-fired silicon solar cell 100b can have an open circuit voltage (Vₒₓ) of about 550 to 660 mV, about 600 to 660 mV, about 640 to 660 mV, or about 645 to 660 mV. The co-fired silicon solar cell structure 100b can have a short circuit current density (Jsc) of about 28 to 39 mA/cm², about 30 to 39 mA/cm², about 34 to 39 mA/cm², or 36 to 39 mA/cm².

Further, the co-fired silicon solar cell structure 100b can include characteristics such as, but not limited to, a bulk lifetime of about 10 to 2500 μs, about 50 to 2500 μs, about 75 to 2500 μs, or about 100 to 2500 μs. The co-fired silicon solar cell structure 100b can include a series resistance (Rs) of about 0.01 to 1 Ω-cm², about 0.50 to 1 Ω-cm², or about 0.80 to 1 Ω-cm². The co-fired silicon solar structure 100b can include a shunt resistance of about 1000 to 5000 kΩ/cm², about 1000 to 3500 kΩ-cm², or about 1000 to 2000 kΩ-cm². The co-fired solar silicon cell structure 100b can include a junction leakage current density (J₀₂) of about 1 to 10 nA/cm², about 4 to 10 nA/cm², or about 7 to 10 nA/cm². The co-fired silicon solar cell structure 100b can include a contact resistance (ρc) of 0.01 to 3 mΩ-cm², about 1 to 3 mΩ-cm², or about 1.5 to 3 mΩ-cm². The co-fired silicon solar cell structure 100b can include a back surface recombination velocity (BSRV) of about 50 to 1000 cm/s, about 50 to 600 cm/s, or about 50 to 500 cm/s, but is should be noted this depends, in part, on the substrate resistivity.

It should be noted that the FF of the co-fired silicon solar cell structure 100b is related, at least in part, to the series resistance (Rs), the shunt resistance, and the junction leakage current density (J_{O2}). In an embodiment, after co-firing, the co-fired silicon solar cell structure 100b has a R, of about 0.80 to 1 Ω-cm², a shunt resistance of about 1000 to 2000 kΩ, and a I₀₂ of about 7 to 10 nA/cm², which indicate excellent ohmic contact and thus an excellent FF of 0.78 to 0.81. The co-firing process results in a co-fired silicon solar cell structure 100b with a reduction in junction leakage current, and a decrease in junction leakage current produces increased Jsc and an increased V_{OC}. Unexpected silicon solar cell structure characteristics 100b are a result of the co-firing process described herein. For example, hydrogen is transferred from the SiNₓ AR layer 104 and the SiNₓ layer 122 to the p-silicon substrate 116 where it is retained in the defects (a process called defect passivation) of the solar cell structure 100b. It should be noted that deviation (e.g., longer holding times) from the co-firing process can drive the hydrogen out of the p-silicon substrate 116. Therefore, appropriate selection of process parameters can enhance the characteristics of the silicon solar cell structure. In this regard, increased defect passivation results in a co-fired silicon solar cell structure 100b with increased bulk lifetime and increased solar cell efficiency.

In one embodiment, among others, the co-fired silicon solar cell structure 100b can have characteristics such as, but not limited to, a fill factor (FF) of about 0.78 to 0.81, an open circuit voltage (Voc) of about 640 to 650 mV, and a short circuit current density J_{sc} of about 34 to 36 mA/cm². Further, the silicon solar cell structure 100b can include a bulk lifetime of 100 to 1000 μs, a series resistance (Rₛ) of about 0.5 to 1 Ω-cm², a shunt resistance of about 1000 to 2000 kΩ, a junction leakage current density (J₀₂) of about 7 to 10 nA/cm², and a back surface recombination velocity (BSRV) of about 50 to 450 cm/s.

In general, the silicon solar cell structure 100b, prior to co-firing, can be introduced to a belt furnace. For clarity, not every step in the process is shown, but one skilled in the art would understand additional steps that may need to be performed. In addition, the steps involved in the process can be performed in different orders, but in general, a p-silicon substrate 116 is provided. An n⁺-type emitter layer 104 is formed on the top-side of the p-silicon substrate 116. Then, a SiNₓ AR layer 106 is formed on the top-side of the n⁺-type emitter layer 104. Also, a SiNₓ layer 122 (or in another embodiment, an Si0₂/SiNₓ stack) is formed on the back-side p-silicon substrate 116. Subsequently, Ag contacts 110 (e.g., part of an Ag metal grid (not shown)) is screen-printed on the top-side of the SiNₓ AR layer 106 using an Ag paste (e.g., PV168 Ag paste) and is dried at a temperature (e.g., about 190 to 220° C.). Then, an Al grid and Al contacts 124 are disposed on the SiNₓ layer 122. After the Ag contacts 110 and Al contacts 124 are formed, the structure is subjected to a co-firing process in the belt furnace under conditions described in more detail below, but includes a temperature ramp up stage, a temperature holding stage, and a temperature ramp down stage. Post co-firing treatments can also be conducted to complete the silicon solar cell formation process.

FIG. 5 illustrates a flowchart 300 describing a representational method of the fabrication process for the silicon solar cell structure 100b shown in FIG. 4. In Block 302 an untreated p-silicon substrate having a top-side and a back-side is provided. The p-silicon substrate can include substrates such as, but not limited to, EFG Si ribbon, string Si ribbon, FZ Si, Cz Si, or cast mc-Si. In another embodiment, the p-silicon substrate can be a Ga doped p-silicon substrate. The Ga doped p-silicon substrate can include substrates such as, but not limited to, a Ga doped Si wafer, EFG Ga doped Si ribbon, string Ga doped Si ribbon, FZ Ga doped Si, Cz Ga doped Si, or cast Ga doped me-Si.

In Block 304, a n⁺-type emitter layer is formed on the top-side of the p-silicon substrate. The n⁺-type emitter can include n⁺-type emitters as described above. In forming the n⁺-type emitter layer, the p-silicon substrate samples can be cleaned and diffused using a liquid POCl₃ source in a tube furnace, for example. Spin-on, print-on, and spray-on phosphorus as well as and drive-in (at set temperatures depending on the required emitter sheet resistances) in a belt-furnace, a RTP, or a tube furnace.

In Block 306, a SiNₓ AR layer 106 is positioned on the n⁺-type emitter. This process includes, but is not limited to, a pretreatment of ammonia plasma in-situ followed by the positioning of a low frequency (e.g., about 50 to 100 kHz) SiNₓ layer at about 400 to 450° C. in a direct plasma enhanced chemical vapor deposition (PECVD) SiN, reactor at about 750 to 800 A. Further, NH₃ and SiH₄ gases are present in the PECVD reactor and react to form the SiNₓ AR layer. Additional methods include direct PECVD (13.6 MHz) or remote PECVD (2.45 GHz) performed at temperatures between about 350-450° C., for example. As a result, a large source of atomic hydrogen is created not only in the SiNₓ AR layer but also in a very thin Si layer underneath the SiNₓ AR layer. This is a result of high-energy ion bombardment, due to the low frequency SiNₓ positioning. In another embodiment, another material (e.g., MgF) can also be used to coat the SiNₓ AR layer to form a double layer AR coating.

In Block 308, a SiNₓ layer (a different layer from the SiNₓ AR layer) is disposed on the back-side of the p-silicon substrate. This process includes, but is not limited to, a pretreatment of ammonia plasma in-situ followed by the positioning of a low frequency (e.g., about 50 to 100 kHz) SiNₓ layer at about 400 to 450° C. in a direct plasma enhanced chemical vapor deposition (PECVD) SiNₓ reactor at about 250 to 800 A. Further, NH₃ and SiH₄ gases are present in the PECVD reactor and react to form the SiNₓ layer. Additional methods include direct PECVD (13.6 MHz) or remote PECVD (2.45 GHz) performed at temperatures between 350-450° C., for example. As a result, a large source of atomic hydrogen is created not only in the SiNₓ layer but also in a very thin Si layer underneath the SiNₓ layer. This is a result of high-energy ion bombardment, due to the low frequency SiNₓ positioning. It should be noted that the formation of the SiNₓ AR layer and the SiNₓ layer can be performed at the same time. It should also be noted that in an alternative embodiment, a silicon dioxide/silicon nitride stack layer could be used instead of the SiNₓ layer.

In Block 310, Ag contacts, are positioned on portions of the SiNₓ AR layer using an Ag paste such as, but not limited to, PV168 paste (produced by DuPont) Ferro CN33-455 and Ferro CN33-460. The Ag contact can be positioned using techniques such as, but not limited to, a process in which Ag paste is screen-printed on the top-side of the SiNₓ AR layer. It should also be noted that photolithography and laser grooved techniques can be used to provide front metal contacts to silicon solar cells.

In Block 312, Al contacts are screen-printed on the back-side of the SiNₓ layer. The Al contact can be positioned using, but not limited to, an Al paste which can be disposed using techniques such as, but not limited to, a process in which Al paste is screen printed on the back of the SiNₓ layer and dried at about 190 to 220° C. to form the Al contact layer on the back-side of the SiNₓ layer. The Al paste can include, but is not limited to FX53-038, and FX53-100 and FX53-101 or other aluminum paste, as may be determined.

In Block 314, a rapid belt co-firing process can be used to treat the silicon solar cell structure 100b. The rapid co-firing process involves a simultaneous firing process. The co-firing process includes a temperature ramp up process. The ramp up process is performed at a ramp up rate of about 50 to 100° C./s, about 50 to 80° C./s, or about 50 to 60° C./s to reach the temperature of about 700 to 900° C., about 750 to 850° C., or about 740 to 780° C. Then, the co-firing process includes a temperature holding stage. In the temperature holding phase, the firing and hold time is about 1 to 5 seconds, about 1 to 3 seconds, and about 1 to 2 seconds, each at a temperature of about 700 to 900° C., about 750 to 850° C., or about 740 to 780° C. The shorter holding time results in maximum lifetime enhancement due to the higher retention of the hydrogen in the defect sites. Then, the co-firing process includes a ramp down stage. The ramp down stage includes reducing the temperature according to a ramp down rate of about 50 to 100° C./s, about 50 to 80° C./s, or about 50 to 60° C./s.

The rapid co-firing process is controlled, in part, by the belt speed and temperature setting in each zone of the belt furnace. The temperature in each zone or stage and the belt speed can each be set to achieve the temperature parameters described above. For example, the belt speed can be about 15 to 100 inches per minute (ipm), 50 to 100 ipm, 80 to 100 ipm, or 100 to 120 ipm.

Although not intending to be bound by theory, the co-firing process described above, and the way in which the process is conducted, provide unexpected results. For example, the co-firing temperature and time exposed to the temperature allow for the simultaneous formation of front Ag contacts and Al back-surface field (p⁺ layer) when the Ag contacts fire through the SiNₓ layer. Specifically, the co-firing steps result in the formation of a uniform back-surface field (BSF) (or p⁺ layer) on the back-side of the co-fired solar cell structure 100b. The co-firing process results in the etching of the SiNₓ AR layer by the glass frit contained in the Ag contacts to form a contact with the n⁺-type emitter layer, which allows n⁺-type emitter layer of higher sheet resistance values to be used (as described above). In addition, the co-firing process results in the etching of the SiNₓ layer by the Al contacts to form a contact with the p-silicon substrate, which allows selective BSF formation only in the contacted region. Further the co-firing process produces a solar cell structure 100b with unexpected characteristics such as but not limited to, an increased defect passivation (in low quality silicon substrates), which results in increased J_{sc}, increased V_{oc}, and increased FF. The co-firing process in conjunction with fast ramp-up also results in a more uniform Al BSF and a decreased BSRV. These above-described variables result in an increased solar cell bulk lifetime and increased solar cell efficiency, which are unexpected and are obtained using the ramp up stage, hold stage, and ramp down stage, as described above.

In Block 316, post belt co-firing treatment can optionally be conducted. Following the co-firing event, the Ag contacts can be covered with photoresist, for example, to enable the edge isolation of the cells with the dicing saw and/or a photolithography process followed by etching in, for example, a buffered oxide etchant (BOE) to remove the shunting path. The most common approach is the isolation of the cells using dicing of each silicon wafers, without the use of photolithography and etching thereafter, followed by a forming gas annealing process at about 350 to 450° C. for a specified time of about 15 to 20 minutes, for example.

It should also be noted that the area of the silicon solar cell structure 100b could alter the sequence of the process described above. For example, for large area solar cells (e.g., about 100 to 300 cm², and about 100 cm², about 156 cm², about 225 cm², and the like), the edge isolation could be performed after Block 304 and before Block 306. Other modifications to the sequence can be performed as well to produce the silicon solar cell structure 100b.

As discussed above, the silicon solar cell structure 100b can be co-fired in a similar manner as described above for silicon solar cell structure 100a and results in the similar benefits as described in reference with silicon solar cell structure 100a.

For the purposes of illustration only, the co-fired silicon solar cell structure 100b is described with particular reference to the below-described fabrication method. The fabrication method is described from the point of view shown in FIG. 4.

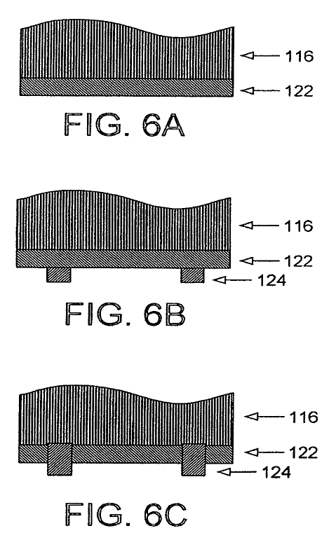

For clarity, some portions of the fabrication process are not included in FIGS. 6A through 6C. The following fabrication process is not intended to be an exhaustive list that includes every step in the fabrication of the co-fired silicon solar cell structure 100b. In addition, the fabrication process is flexible and the process steps may he performed in a different order than the order illustrated in FIGS. 6A through 6C. For clarity, the steps for fabricating the front-side of the co-fired silicon solar cell structure 100b are not shown in FIGS. 6A through 6C since they are similar to the front-side fabrication of the co-fired silicon solar cell structure 100a shown in FIGS. 3A through 3F.

In general, the back-side of the silicon solar cell structure 100b can be formed in a manner described in FIGS. 6A through 6C. FIGS. 6A through 6C are schematics that illustrate an exemplary method of forming the silicon solar cell structure 100b shown in FIG. 4. FIG. 6A illustrates a SiNₓ layer 122 disposed on the back-side of a p-silicon substrate 116.

FIG. 6B illustrates the positioning of an Al grid and Al contacts 124 on the back-side of the SiNₓ layer 122. The Al grid and Al contacts 124 can be positioned using techniques such as, but not limited to, a process in which Al paste is screen-printed on the back-side of the SiNₓ layer 122 and dried at a specified temperature.

FIG. 6C illustrates the co-fired silicon solar cell structure 100b after rapid co-firing, where the Al contacts 124 are co-fired through the SiNₓ layer 122 and are in electrical contact with the p-silicon substrate 116. In addition, the co-fired silicon solar cell structure 100b can be post treated similar to that described in reference to FIGS. 1 through 3.

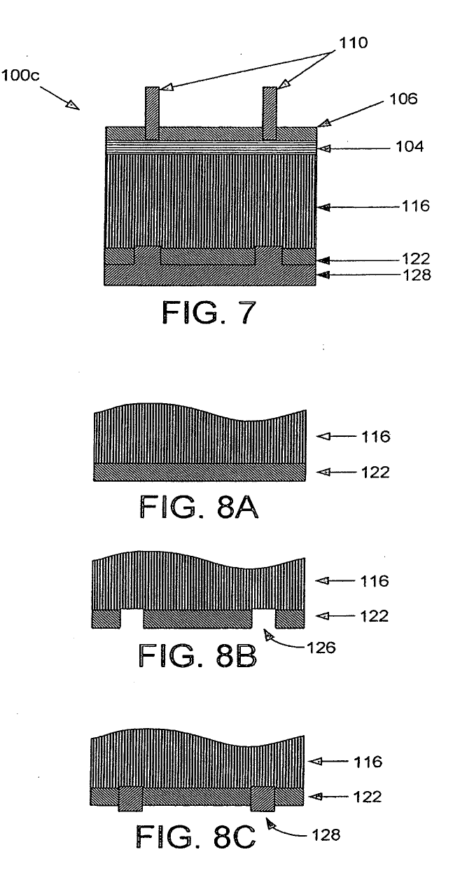

FIG. 7 illustrates an exemplary embodiment of a screen-printed contact co-fired silicon solar cell structure 100c (e.g., after co-firing of the metal screen-printed metal contacts process) (hereinafter “co-fired silicon solar cell structure 100c”). The co-fired silicon solar cell structure 100c includes, but is not limited to, a treated p-silicon substrate 116 having a top-side and a back-side, a n⁺-type emitter layer 104 formed on the top-side of the treated p-silicon substrate 116, a silicon nitride (SiNₓ) anti-reflective (AR) layer 106 positioned on the top-side of the n⁺-type emitter layer 104, a plurality of Ag contacts 110 (part of the Ag grid, where only the Ag contacts are shown) positioned on portions of the SiNₓ AR coating 106, a SiNₓ layer 122 disposed on the back-side of the p-silicon substrate 116, a fired screened printed aluminum (Al) grid and Al contacts 128 disposed on the back-side of the SiNₓ layer 122, where the Al grid and Al contacts 128 are in electrical communication with the p-silicon substrate 116, and a back-surface field (BSF) layer (not shown) positioned between the back-side (i.e., back, rear, and rear-side of the p-silicon substrate 116) of the p-silicon substrate 116 (i.e., the side opposite the n⁺-type emitter layer) and the Al contacts 128. The Ag contacts 110 in electronically connected to the n⁺-type emitter layer. In another embodiment, the p-silicon substrate 116 can be a Ga doped p-silicon substrate such as that described above in reference to FIGS. 1 and 2 and the corresponding text.

The p-silicon substrate 116, n⁺-type emitter layer 104, SiNₓ AR layer 106, the Ag contacts 110, and SiNₓ layer 122, are similar to the layers described in reference to FIGS. 1, 2, and 4 through 6 above. The co-fired silicon solar cell structure 100c can be fabricated in a manner similar to that shown in FIG. 5 with a few changes mentioned below in regard to the Al grid and Al contacts 128.

FIG. 7 illustrates two Al contacts 128, but three or more Al contacts can be used. The Al grid and Al contacts 128 can be made of aluminum Fx53-100, and other types of aluminum. In an embodiment, the Al is capable of firing through the silicon nitride at temperatures that are not high enough to destroy the bulk passivation. The Al grid and Al contacts 128 can be disposed on the SiNₓ layer 122 using techniques such as, but not limited to, spin coating, evaporation, and the like.

Prior to disposing the Al grid and Al contacts 128, a via 126 is etched and/or drilled through the SiNₓ layer 122. Therefore, when the Al grid and Al contacts 128 are disposed onto the SiNₓ layer 122, a portion of the Al (i.e., the Al contacts) are disposed into the vias and contact the p-silicon substrate 116. This is in contrast to the co-firing process described in reference to FIG. 4. However, in an embodiment, the via 126 should be clear of SiNₓ so that a uniform BSF can be formed underneath the Al metal after the co-firing process. In an embodiment, the Al grid and Al contacts 128 should only contact the p-silicon through the vias 126. The Al grid should not be able to punch through the SiNₓ layer 122. This combination of dielectric and metal should provide an effective back reflector.

The via 126 through SiNₓ can be drilled/etched using techniques such as, but not limited to, laser drilling, mechanical drilling, or chemical etching (e.g., plasma etch and using phosphoric acid dispensed on the location of interest in conjunction with dry and clean steps).

Upon co-firing, the Al contacts 128 are subsequently in electrical communication with the co-fired p-type silicon substrate 116. In addition, a uniform Al back-surface field (BSF) layer disposed between the Al contact 128 and the co-fired p-type silicon substrate 116. A difference between the process sequence for preparing structures 100b and 100c is that, in the process for forming silicon solar cell structure 100b, the Al should punch through the SiNₓ during the co-firing process. In the process for forming the silicon solar cell structure 100c, the Al should not fire through the SiNₓ but should contact the p-silicon through the vias only. Both the Al and Al contacts 128 are applied before the final firing at the set temperatures.

The co-fired silicon solar cell structure 100c can have characteristics such as, but not limited to, those described above in reference to co-fired silicon solar cell structure 100b. The characteristics include, but are not limited to, fill factor (FF) an open circuit voltage (V_{oc}), a short circuit current density (J_{sc}), a bulk lifetime, a series resistance (Rₛ), a shunt resistance, a junction leakage current density (J₀₂), a contact resistance (ρc), a back surface recombination velocity (BSRV), and other characteristic described in reference to co-fired silicon solar cell structure 100b.

In general, the silicon solar cell structure 100c, prior to co-firing, can be introduced to a belt furnace. For clarity, not every step in the process is shown, but one skilled in the art would understand additional steps that may need to be performed. In addition, the steps involved in the process can be performed in different orders, but in general, a p-silicon substrate 116 is provided. An n⁺-type emitter layer 104 is formed on the top-side of the p-silicon substrate 116. Then, a SiNₓ AR layer 106 is positioned on the topside of the n⁺-type emitter layer 104 and on the p-silicon substrate layer 122. Then, vias 126 are etched and/or drilled in the SiNₓ layer 122. Subsequently, Ag contacts 110 (e.g., part of an Ag metal grid (not shown)) are screen-printed on the top-side of the SiNₓ AR layer 106 using an Ag paste (e.g., PV168, CN33-455 and, CN33-462 Ag, paste) and is dried at a temperature (e.g., about 190 to 220° C.). The Al grid and Al contacts 128 are disposed on the SiNₓ layer 122 by screen-printing, where some of the aluminum enters the via to form the aluminum contacts. After the Ag contacts 110 and Al grid and contacts 128 are formed, the structure is subjected to a co-firing process in the belt furnace under conditions described in more detail herein, but include a temperature ramp up stage, a temperature holding stage, and a temperature ramp down stage. Post co-firing treatments can also be conducted to complete the silicon solar cell formation process. For large area cells (e.g., about 100 to 300 cm², and about 100 cm², about 156 cm², about 225 cm², and the like), the edge isolation step is carried out prior to SiNₓ deposition.

As discussed above, the silicon solar cell structure 100c can be co-fired in a similar manner as described above for silicon solar cell structure 100a and 100b and results in the similar benefits as described in reference with silicon solar cell structure 100a and 100b.

For the purposes of illustration only, the co-fired silicon solar cell structure 100c is described with particular reference to the below-described fabrication method. The fabrication method is described from the point of view shown in FIG. 7.

For clarity, some portions of the fabrication process are not included in FIGS. 8A through 8C. The following fabrication process is not intended to be an exhaustive list that includes every step in the fabrication of the co-fired silicon solar cell structure 100c. In addition, the fabrication process is flexible and the process steps may be performed in a different order than the order illustrated in FIGS. 8A through 8C. For clarity, the steps for fabricating the front-side of the co-fired silicon solar cell structure 100c are not shown in FIGS. 8A through 8C since they are similar to the front-side fabrication of the co-fired silicon solar cell structure 100a shown in FIGS. 3A through 3F.

In general, the back-side of the silicon solar cell structure 100c can be formed in a manner described in FIGS. 8A through 8C. FIGS. 8A through 8C are schematics that illustrate an exemplary method of forming the silicon solar cell structure 100c shown in FIG. 7. FIG. 8A illustrates a SiNₓ layer 122 disposed on the back-side of a p-silicon substrate 116.

FIG. 8B illustrates the SiNₓ layer 122 after etching and/or drilling to form vias 126. The vias 126 can penetrate completely through the SiNₓ layer 122 or partially through the SiNₓ layer 122. In one embodiment, the vias 126 are drilled using a laser.

FIG. 8C illustrates the positioning of an Al grid and Al contacts 124 on the back-side of the SiNₓ layer 122, where a portion of the Al enters the vias 126. The Al grid and Al contacts 124 can be positioned using techniques such as, but not limited to, a process in which Al paste is screen-printed on the back-side of the SiNₓ layer 122 and dried at a specified temperature. Subsequently, the silicon solar cell structure can be co-fired and treated similar to that described in reference to FIGS. 1 through 3.

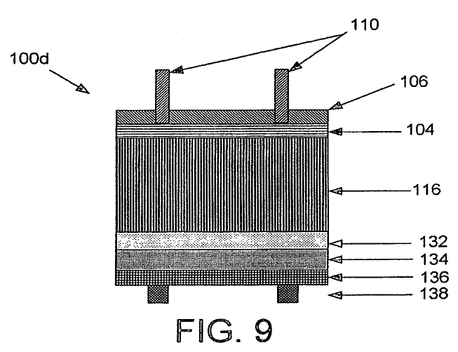

FIG. 9 illustrates an exemplary embodiment of a screen-printed contact two-step fired silicon solar cell structure 100d (e.g., after co-firing of the metal screen-printed metal contacts process) (hereinafter “fired silicon solar cell structure 100d”). The fired silicon solar cell structure 100d includes, but is not limited to, a treated p-silicon substrate 116 having a top-side and a back-side, a n⁺-type emitter layer 104 formed on the top-side of the treated p-silicon substrate 116, a silicon nitride (SiNₓ) anti-reflective (AR) layer 106 positioned on the top-side of the n⁺-type emitter layer 104, a plurality of Ag contacts 110 (part of the Ag grid, where only the Ag contacts are shown) positioned on portions of the SiNₓ AR coating 106, an intrinsic amorphous silicon 132 disposed on the back-side of the p-type silicon substrate 116, a p-type amorphous silicon layer 134 disposed on the back-side of the intrinsic amorphous silicon substrate 132, and transparent conducting oxide layer 136 (e.g. an indium-tin-oxide or a zinc oxide layer) disposed on the back-side of the p-type amorphous silicon layer 134. In an embodiment, a screen-printed aluminum grid 138 is disposed on the back-side of the transparent conducting oxide layer 136. The Ag contacts 110 are electronically connected to the n⁺-type emitter layer 104. In another embodiment, the p-silicon substrate 116 can be a Ga doped p-silicon substrate such as that described above in reference to FIGS. 1 and 2 and the corresponding text.

The p-silicon substrate 116, n⁺-type emitter layer 104, SiNₓ AR layer 104, and the Ag contacts 110, are similar to the layers described in reference to FIGS. 1, 2, and 4 through 6 above.

The fired silicon solar cell structure 100d can have characteristics such as, but not limited to, those described above in reference to co-fired silicon solar cell structure 100a, 100b, and 100c. The characteristics include, but are not limited to, fill factor (FF) an open circuit voltage (V_{oc}), a short circuit current density (J_{sc}), a bulk lifetime, a series resistance (Rₛ), a shunt resistance, a junction leakage current density (J₀₂), a contact resistance (ρc), a back surface recombination velocity (BSRV), and other characteristics described in reference to co-fired silicon solar cell structure 100a, 100b, and 100c. It should be noted that the fired silicon solar cell structure 100d having an amorphous back layer (intrinsic and doped) provides much better back surface passivation than the conventional cells.

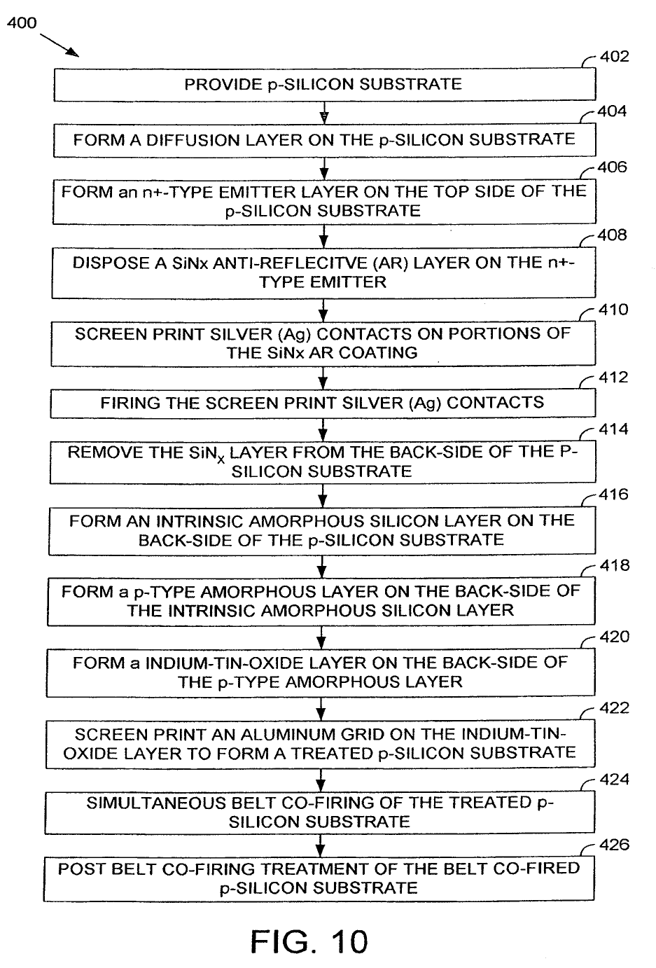

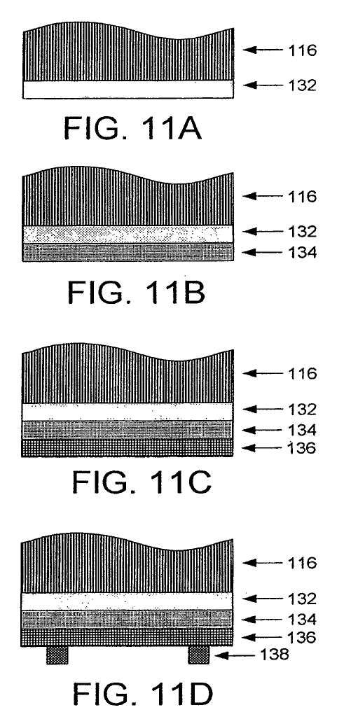

FIG. 10 illustrates a flowchart 400 describing a representational method of the fabrication process for the fired silicon solar cell structure 100d shown in FIG. 9. In Block 402 an untreated p-silicon substrate having a top-side and a back-side is provided. The p-silicon substrate can include substrates such as, but not limited to, EFG Si ribbon, string Si ribbon, FZ Si, Cz Si, or cast mc-Si. In another embodiment, the p-silicon substrate can be a Ga doped p-silicon substrate. The Ga doped p-silicon substrate can include substrates such as, but not limited to, a Ga doped Si wafer, EFG Ga doped Si ribbon, string Ga doped Si ribbon, FZ Ga doped Si, Cz Ga doped Si, or cast Ga doped mc-Si.

In Block 404, a diffusion mask (e.g., SiNₓ or a Si0₂ diffusion mask) is disposed on the untreated p-silicon substrate. The SiNₓ diffusion mask can be formed using techniques such as, but not limited to, PECVD. The Si0₂ diffusion mask can be formed using techniques such as, but not limited to, thermal growth, PECVD deposition, and spin-on Si glass or spray-on silicon glass.

In Block 406, a n⁺-type emitter layer is formed on the top-side of the p-silicon substrate. The n⁺-type emitter can include n⁺-type emitters as described above. In forming the n⁺-type emitter layer, the p-silicon substrate samples can be cleaned and diffused using a liquid POCl₃ source in a tube furnace, for example. Spin-on, print-on, and spray-on phosphorus as well as drive-in (at set temperatures depending on the required emitter sheet resistances) in a belt-furnace, a RTP, or a tube furnace.

In Block 408, a SiNₓ AR layer is positioned on the n⁺-type emitter. This process includes, but is not limited to, a pretreatment of ammonia plasma in-situ followed by the positioning of a low frequency (e.g., about 50 to 100 kHz) SiNₓ AR layer at about 400 to 450° C. in a direct plasma enhanced chemical vapor deposition (PECVD) SiNₓ reactor at about 750 to 800 A. Further, NH₃ and SiH₄ gases are present in the PECVD reactor and react to form the SiNₓ AR layer. Additional methods include direct PECVD (13.6 MHz) or remote PECVD (2.45 GHz) performed at temperatures between 350-450° C., for example. As a result, a large source of atomic hydrogen is created not only in the SiNₓ AR layer, but also in a very thin Si layer underneath the SiNₓ AR layer. This is a result of high-energy ion bombardment, due to the low frequency SiNₓ positioning. In another embodiment, another material (e.g., MgF) can also be used to coat the SiNₓ AR layer to form a double layer AR coating.

In Block 410, Ag contacts, are positioned on portions of the SiNₓ AR layer using an Ag paste such as, but not limited to, PV 168 paste (produced by DuPont) Ferro CN33-455 and Ferro CN33-460. The Ag contact can be positioned using techniques such as, but not limited to, a process in which Ag paste is screen-printed on the top-side of the SiNₓ AR layer. It should also be noted that photolithography and laser grooved techniques can be used to provide front metal contacts to silicon solar cells.

In Block 412, the Ag contacts are belt fired at temperatures similar to those used in reference to the 100a and the 100b structures.

In Block 414, the diffusion mask is removed from the back-side of the p-silicon substrate using techniques such as, but not limited to, chemical removal, photolithography, and the like.

In Block 416, an intrinsic amorphous silicon layer is disposed on the back-side of the co-fired p-type silicon substrate. The intrinsic amorphous silicon layer has a front-side and a back-side. The intrinsic amorphous silicon layer can be formed using techniques such as, but not limited to, PECVD with SiH₄ and NH₃. The intrinsic amorphous silicon layer can have a thickness of about 2 nm to 3 nm, 4 nm to 6 nm, or 6 nm to 10 nm.

In Block 418, a p-type amorphous silicon layer is disposed on the back-side of the intrinsic amorphous silicon layer. The p-type amorphous silicon layer has a front-side and a back-side. The p-type amorphous silicon layer can be formed using techniques such as, but not limited to, PECVD with SiH₄, and NH₃. The p-type amorphous silicon layer can have a thickness of about 3 nm to 5 nm, 6 nm to 7 nm, or 7 nm to 10 nm.

In Block 420, a transparent conducting oxide layer is disposed on the back-side of the p-type amorphous silicon layer. The transparent conducting oxide layer has a front-side and a back-side. The transparent conducting oxide layer can be formed using techniques such as, but not limited to, sputtering and evaporation. The transparent conducting oxide layer can have a thickness of about 5 nm to 10 nm, 5 nm to 15 nm, or 5 nm to 20 nm.

In Block 422, Al grid is screen-printed on the back-side of the transparent conducting oxide layer. The Al grid can be positioned using, but not limited to, an Al paste which can be disposed using techniques such as, but not limited to, a process in which Al paste is screen printed on the back of the transparent conducting oxide layer and dried at about 190 to 220° C. to form the Al grid layer on the back-side of the transparent conducting oxide layer.

In Block 424, the Al contacts are subject to a low temperature (about 150-250° C.) firing. Although not intending to be bound by theory, the firing process described above, and the way in which the process is conducted, provide unexpected results. The Al contact firing applicable to this structure is a two-step firing. The advantage of this is that the Al contact firing done after the amorphous silicon deposition/TCO is performed at a temperature that does not lead to the effusion of hydrogen. For example, the firing temperature and time exposed to the temperature allow for the simultaneous formation of front Ag contacts 110 and Al back-surface field (not shown) (p⁺ layer) when the Ag contacts fire through the SiNₓ AR layer. Specifically, the firing steps result in the formation of a uniform back-surface field (BSF) (or p⁺ layer) on the backside of the fired solar cell structure 110d. The firing process results in the etching of the SiNₓ AR layer by the glass frit contained in the Ag contacts to form a contact with the n⁺-type emitter layer, which allows n⁺-type emitter layer of higher sheet resistance values to be used (as described above). Further, the firing process produces a tired solar cell structure 100d with unexpected characteristics such as, but not limited to, an increased defect passivation (in low quality silicon substrates), which results in increased J_{sc}, increased V_{oc}, and increased FF. The firing process also results in a more uniform Al BSF and a decreased BSRV. These above-described variables result in an increased solar cell bulk lifetime and increased solar cell efficiency, which are unexpected and are obtained using the ramp up stage, hold stage, and ramp down stage, as described above.

In Block 426, post belt firing treatment can optionally be conducted. Following the firing event, the Ag contacts 110 can be covered with photoresist, for example, to enable the edge isolation of the cells with the dicing saw and/or a photolithography process followed by etching in, for example, a buffered oxide etchant (BOE) to remove the shunting path. The most common approach is the isolation of the cells using dicing of each silicon wafers without the use of photolithography and etching thereafter, followed by a forming gas annealing process at about 350 to 450° C. for a specified time of about 15 to 20 minutes, for example. It should also be noted that the area of the fired silicon solar cell structure 100d could alter the sequence of the process described above. For example, for large area solar cells, the edge isolation could be performed after Block 406 and before Block 408. Other modifications to the process sequence can be performed to produce the fired silicon solar cell structure 100d as well.

For the purposes of illustration only, the two-step-fired silicon solar cell structure 100d is described with particular reference to the below-described fabrication method. The fabrication method is described from the point of view shown in FIG. 9.

For clarity, some portions of the fabrication process are not included in FIGS. 11A through 11D. The following fabrication process is not intended to be an exhaustive list that includes every step in the fabrication of the fired silicon solar cell structure 100d. In addition, the fabrication process is flexible and the process steps may be performed in a different order than the order illustrated in FIGS. 11A through 11D. For clarity, the steps for fabricating the front-side of the fired silicon solar cell structure 100d are not shown in FIGS. 11A through 11D since they are similar to the front-side fabrication of the co-fired silicon solar cell structure 100a shown in FIGS. 3A through 3F.

In general, the backside of the fired silicon solar cell structure 100d can be formed in a manner described in FIGS. 11A through 11D. FIGS. 11A through 11D are schematics that illustrate an exemplary method of forming the fired silicon solar cell structure 100d shown in FIG. 9. FIG. 1A illustrates an intrinsic amorphous silicon layer 132 disposed on the backside of a p-silicon substrate 116. The intrinsic amorphous silicon layer 132 can be formed using techniques such as, but not limited to, about 2 nm, about 5 nm, or about 10 nm.

FIG. 11B illustrates a p-type amorphous silicon layer 134 disposed on the backside of the i-type amorphous silicon layer 132. The p-type amorphous silicon layer 134 can be formed using techniques such as, but not limited to, PECVD.

FIG. 11C illustrates a transparent conducting oxide layer 136 (e.g. indium tin oxide layer) disposed on the backside of the p-type amorphous silicon layer 134. The transparent conducting oxide layer 136 can be formed using techniques such as, but not limited to, sputtering, evaporation, and printing.

FIG. 11D illustrates Al grid 138 disposed on the backside of the transparent conducting oxide layer 136. The Al grid 138 can be positioned using, but not limited to, an Al paste.

Now having described silicon solar cell structure and its methods of fabrication in general, Example 1 describes some embodiments of the silicon solar cell structure and uses thereof. While embodiments of the silicon solar cell structure and methods of fabrication are described in connection with Example 1 and the corresponding text and figures, there is no intent to limit embodiments of the silicon solar cell structure and its methods of fabrication to these descriptions. On the contrary, the intent is to cover all alternatives, modifications, and equivalents included within the spirit and scope of embodiments of the present disclosure.

It should be noted that ratios, concentrations, amounts, dimensions, and other numerical data may be expressed herein in a range format. It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a range of “about 0.1% to about 5%” should be interpreted to include not only the explicitly recited range of about 0.1% to about 5%, but also include individual ranges (e.g., 1%, 2%, 3%, and 4%) and the sub-ranges (e.g., 0.5%, 1.1%, 2.2%, 3.3%, and 4.4%) within the indicated range.

It should be emphasized that the above-described embodiments and the following Examples of the present disclosure are merely possible examples of implementations, and are merely set forth for a clear understanding of the principles of the disclosure. Many variations and modifications may be made to the above-described embodiments. All such modifications and variations are intended to be included herein within the scope of this disclosure and protected by the following claims.

### EXAMPLE 1

Now having described the embodiments of the nanostructure in general, Example 1 describes some embodiments of the nanostructure and uses thereof. The following is a non-limiting illustrative example of an embodiment of the present disclosure that is described in more detail in V. Meemongkolkiat, K. Nakayashiki, A. Rohatgi, G. Crabtree, J. Nickerson and T. L. Jester, “Resistivity and lifetime variation along commercially grown Ga- and G-doped Czochralski Si ingots and its effect on light-induced degradation and performance of solar cells” submitted (in confidence) to Progress in Photovoltaics, March 2005, which is incorporated herein by reference. This example is not intended to limit the scope of any embodiment of the present disclosure, but rather is intended to provide some experimental conditions and results. Therefore, one skilled in the art would understand that many experimental conditions can be modified, but it is intended that these modifications be within the scope of the embodiments of the present disclosure.

A systematic study of the variation in resistivity and lifetime on cell performance, before and after light-induced degradation (LID), was performed along the commercially grown B- and Ga-doped Czochralski (Cz) ingots. Manufacturable screen-printed solar cells were fabricated and analyzed from different locations on the ingots. Despite the large variation in resistivity (0.57 Ω-cm to 2.5 Ω-cm) and lifetime (100-1000 μs) in the Ga-doped Cz ingot, the efficiency variation was found to be ≦0.5% with an average efficiency of ˜17.1%. No LID was observed in these cells. In contrast to the Ga-doped ingot, the B-doped ingot showed a relatively tight resistivity range (0.87 Ω-cm to 1.22 Ω-cm), resulting in smaller spread in lifetime (60-400 μs) and efficiency (16.5-16.7%) along the ingot. However, the LID reduced the efficiency of these B-doped cells by about 1.1% absolute. Additionally, the use of thinner substrate and higher resistivity (4.3 Ω-cm) B-doped Cz was found to reduce the LID significantly, resulting in an efficiency reduction of 0.5-0.6% as opposed to >1.0% in ˜1 Ω-cm 17% efficient screen-printed cells. As a result, Ga-doped Cz cells gave 1.5% and 0.7% higher stabilized efficiency relative to 1 Ω-cm and 4.3 Ω-cm B-doped Cz Si cells, respectively.

It is well known that solar cells fabricated on conventional B-doped Czochralski (Cz) Si suffer from degradation caused by the illumination or injection of carriers. It has also been established that this light-induced degradation (LID) effect results from the presence of B and 0 simultaneously in Si. Therefore, the LID effect can be removed by eliminating either B or O from Si. Several alternatives have been suggested and attempted in the literature to avoid LID in Cz Si including the 1) use of alternative dopants such as P for n-type and Ga for p-type Cz Si; 2) reduction of interstitial oxygen to an acceptable level by growing Magnetic Cz Si; 3) use of higher resistivity B-doped Cz; and 4) process optimization. Doping the Si ingot with Ga has advantages over other methods as it provides complete elimination of LID without modifying the cell structure or processing equipment. However, there are some drawbacks associated with the implementation of Ga. First, use of Ga dopant gives rise to a complication of managing the silicon feedstock. The other basic drawback of using Ga as a dopant is the low segregation coefficient of Ga in Si (k=0.008). This results in a much wider variation in resistivity along the Ga-doped ingot. If the solar cell fabrication process cannot tolerate this wider resistivity distribution, a significant yield loss in the crystal growth process would result in a substantial cost addition. Many research groups have tried to investigate the solar cell performance as a function of resistivity or the position in the ingot. However, such relationship has never been established for the widely manufactured screen-printed solar cells from Si wafers obtained from B- and Ga-doped commercial Cz ingots grown in the same puller. Therefore, in this study, B- and Ga-doped Cz ingots were grown in an industrial environment at Shell Solar Industries, and the Cz Si wafers from different locations along the Ga- as well as the B-doped ingots were analyzed. Both the ingots were targeted to have resistivity of ˜1 Ω-cm. In addition to the wafers from these two ingots, some B-doped thin wafers with higher resistivity (˜4.3 Ω-cm) were included in the study to explore the reduction in the LID effect as proposed in the literature. All three ingots were grown using the exact same growth method and equipment. The bulk lifetime in all the samples was determined by the contactless photoconductance measurement. Manufacturable screen-printed solar cells were fabricated and analyzed using light IV-measurement.

TABLE I
Description of Cz Si samples used in the study.

| Ingot | Thickness | | | | | | | |
|---|---|---|---|---|---|---|---|---|
| | | | Location | | | | | |
| | | | Tail end | | | | | Seed end |
| Low-p | 290 μm | ρ(Ω · cm) | 1 | 2 | 3 | 4 | 5 | 6 |
| B-doped | | | 0.87 | 0.82 | 0.90 | 0.95 | 1.00 | 1.22 |

| | | | Location | | | | | | | | |
|---|---|---|---|---|---|---|---|---|---|---|---|
| Ga- | 290 μm | ρ(Ω · cm) | 1 | 2 | 3 | 4 | 5 | 6 | 7 | 8 | 9 |
| doped | | | 0.57 | 0.63 | 0.84 | 0.99 | 1.19 | 1.46 | 1.82 | 2.17 | 2.54 |

| | | | |
|---|---|---|---|
| Hi-ρ | 230 μm | ρ(Ω · cm) | 4.3 |
| B-doped | | | |

### EXPERIMENTAL OF EXAMPLE 1

The Si wafers used in this study were taken from different locations along the two Cz Si ingots: six locations from the ˜1 Ω-cm B-doped ingot and nine locations from the 0.5-2.5 Ω-cm Ga-doped ingot were selected (Table I). Additional wafers were taken from a higher resistivity B-doped ingot (˜4.3 Ω-cm) and thinned down to ˜230 μm from ˜290 μm. Table I summarizes all the wafers used in the study. The lifetime was measured on each sample both in the as-grown state and after the phosphorus emitter diffusion. The post-diffusion lifetime was measured on each sample after POCl₃ diffusion at ˜880° C. followed by etching of the sample down to Si bulk. The lifetime measurements were performed after: 1) 200° C. anneal to remove any LID effect; and 2) light-soaking for >20 hrs to obtain the stabilized lifetime after LID. The surface was passivated by iodine/methanol solution during the lifetime measurements.

Screen-printed Al-back surface field (BSF) solar cells (4 cm²) were fabricated on all the wafers in Table I using an industrial process. First, the samples were textured in an alkaline etch and then POCl₃ diffused to obtain a ˜45 Ω/sq. emitter. Subsequently, SiNₓ AR-coating was deposited on the front. All the samples were then subjected to full-area Al screen-printing on the backside, followed by Ag gridline printing on the front. The samples were then co-fired using rapid thermal processing. No special heat treatment was performed to minimize LID as proposed in the literature.

The I-V measurements were taken after annealing the cells at 200° C. to remove the LID effect and to determine the cell performance without the LID. The I-V measurements were repeated on all the cells after light soaking them for >20 firs to obtain the stabilized cell performance after LID.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Although specific terms are employed herein, they are used in a generic and descriptive sense only and not for purposes of limitation.

### RESULTS AND DISCUSSION OF EXAMPLE 1

### Crystal Growth

The crystal growth process appears to be transparent to the use of Ga dopant because same method and equipment was used successfully for B- and Ga-doped Cz growth. In comparison with B-doped Cz Si, the growth of Ga-doped Cz Si does not require an extra effort on the growth control, melt contamination or maintaining structure loss. Maintaining the rate of structure loss is especially important for cost control since it is typically the highest loss category in a Cz crystal growth process. Consequently, no changes to the crystal growth process were necessary to achieve similar yields on Ga-doped ingot.

### Resistivity Distribution:

Table I shows that the growth of low-resistivity B-doped ingot provides samples with a tight resistivity control, ranging from 0.87 Ω-cm to 1.22 Ω-cm. However, the resistivity variation is much larger (0.57-2.54 Ω-cm) in the case of the Ga-doped ingot compared to the B-doped ingot. The resistivity decreases appreciably from seed to tail end of the Ga-doped ingot because of the low segregation coefficient of Ga (k=0.008 compared to B (k=0.8) in Si.

### AS-GROWN AND POST-DIFFUSION LIFETIME OF EXAMPLE 1

### B-Doped Ingots

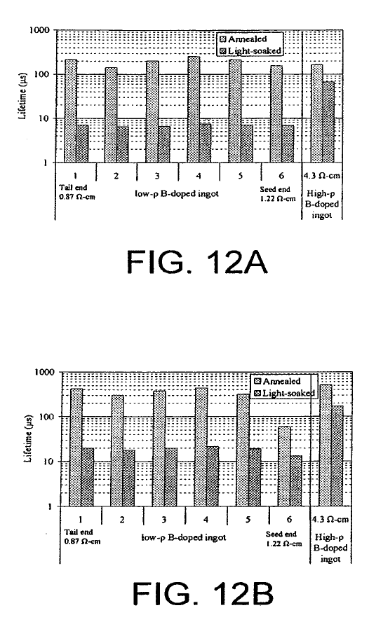

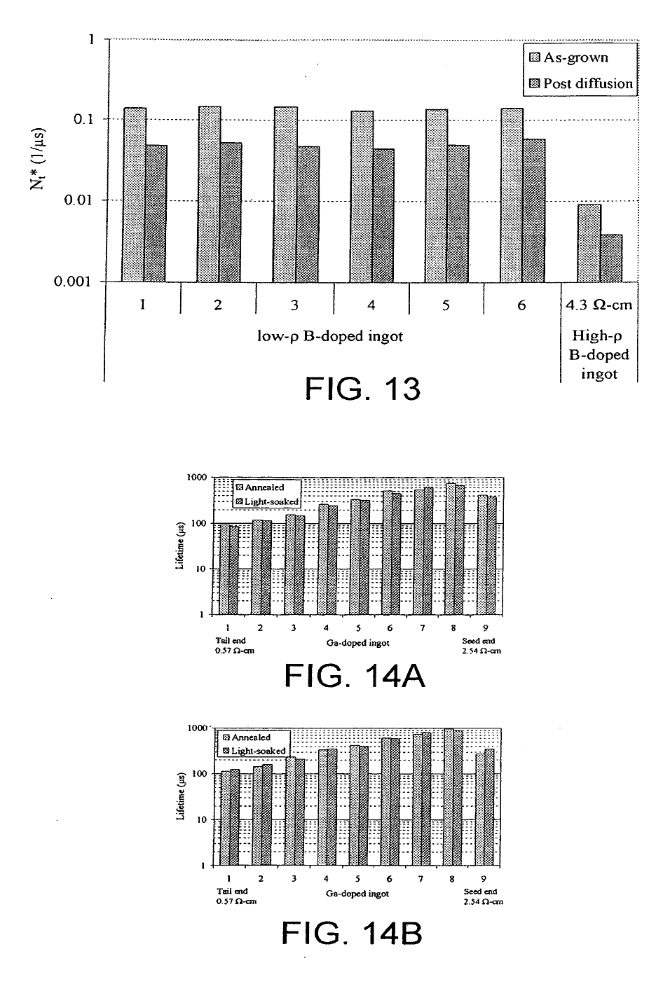

The as-grown and post-diffusion lifetimes before and after LID on wafers from different locations in the low and high resistivity B-doped Cz ingot are summarized in FIGS. 12A and 12B, respectively. The low-resistivity B-doped ingot showed a very tight distribution of the lifetime except at the seed end, where the lifetime was somewhat lower probably due to the swirl defects that occur in macroscopically dislocation-free Si with a high density of point defects. All the bulk lifetime measurements in FIGS. 12A and 12B were performed at an injection level of 2×10¹⁴ cm⁻³.

FIGS. 12A and 12B show that the phosphorus diffusion enhances the light-soaked lifetime significantly. This is attributed to: 1) impurity gettering by phosphorus diffusion; and 2) the reduction of metastable defects (responsible for LID) by high-temperature treatment. For this reason, the lifetime in the finished cell correlates better with the post-diffusion lifetime rather than the as-grown lifetime. To consider the effectiveness of the high temperature process in the reduction of LID, it is useful to first calculate the normalized metastable defect concentration, defined as

Nₜ*=σₙυₜₕNₜ.

This can be calculated from the lifetime in annealed and light-soaked states as follows:

$${N}_{t}^{*} = \frac{1}{{τ}_{light \text{-} soaked}} - \frac{1}{{τ}_{annealed}} \qquad ( 1 )$$

Nₜ* was calculated using eq. (1) and the measured lifetime before and after LID at an injection level of 2×10¹⁴ cm⁻³ for all samples. The Nₜ* values for as-grown and post-diffusion states are shown in FIG. 6. Smaller value of Nₜ* reflects lower concentration of metastable defects (Nₜ) that are responsible for LID. Our data shows that the phosphorus diffusion reduced the metastable defect concentration effectively by a factor of 2.8-3.1 in the low resistivity boron doped samples and by a factor of 2.4 in the high-resistivity boron doped sample. In spite of this respectable improvement, the LID managed to lower the post diffusion lifetime by a factor of 15-20 (from ˜300-400 μs to ˜20 μs) in the low-resistivity (˜1 Ω-cm) B-doped wafers (FIG. 12Bb). The high-resistivity B-doped sample, on the other hand, exhibited a much weaker LID effect due to lower B concentration, resulting in about a factor of three degradation in lifetime from ˜500 μs to ˜170 μs.

### Ga-Doped Ingot:

The as-grown and post-diffusion lifetimes measured at the injection level of 2×10¹⁴ cm⁻³ for the Ga-doped Cz samples are summarized in FIGS. 14A and 14B, respectively. Unlike the B-doped wafers, Ga-doped wafers did not show any LID. However, the post-diffusion lifetime in Ga-doped ingot varied significantly from ˜100 to ˜1000 μs from seed to tail end partly because of the variation in the resistivity. Both resistivity and lifetime increased gradually from tail to seed end except for a drop at the seed end for the same reason (swirl defects) as the B-doped ingot. Notice that the phosphorus diffusion improved the lifetime of Ga-doped wafers by about a factor of 1.3 due to gettering of impurities.

### LID AND PERFORMANCE OF SCREEN-PRINTED SOLAR CELLS OF EXAMPLE 1

### B-Doped Ingots

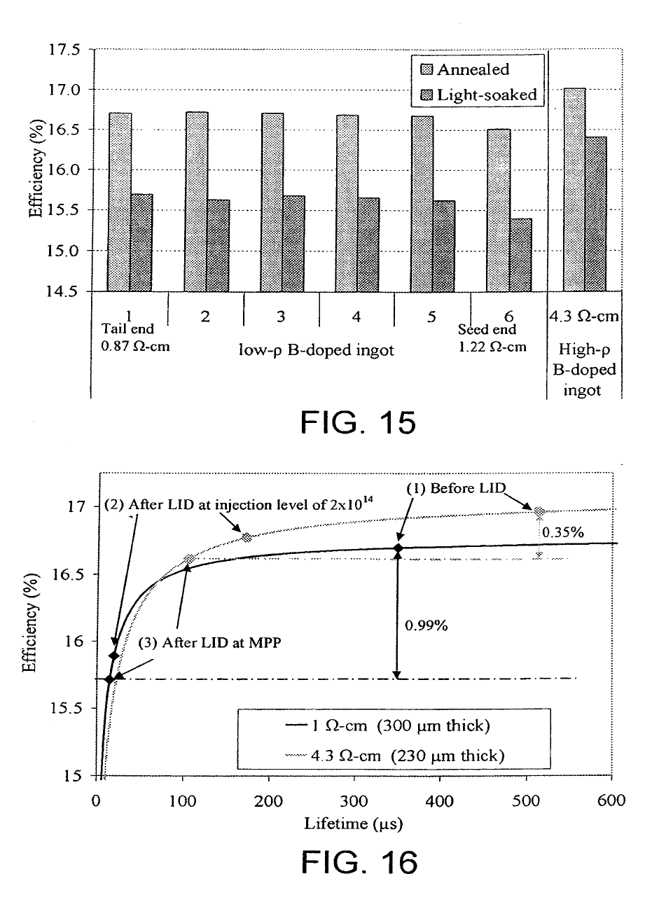

Simple manufacturable 4 cm² screen-printed cells were fabricated with texturing. Al-BSF and SiNₓ PECVD single-layer AR coating (Section 2). The efficiency of the solar cells fabricated on wafers taken from different locations on B-doped ingots is plotted in FIG. 15. Both annealed (no LID) and light-soaked (after LID) states are included in FIG. 15 to assess the LID effect.

The efficiency prior to the LID in the low-resistivity B-doped ingot was quite uniform (˜16.7%), except at the seed end where the efficiency dropped slightly to 16.5%. This is entirely consistent with the lifetime data in FIG. 12B, which showed fairly uniform lifetime except at the seed end. However, the efficiency of all the low-resistivity B-doped cells decreased significantly by about 1.1% absolute after the light soaking, resulting in a final efficiency of only ˜15.6%. This is also consistent with FIG. 12B, which shows that after the diffusion and light-soaking, the lifetime in all the wafers dropped to ˜20 μs after LID.

The high-resistivity (4.3 Ω-cm) thin (230 μm) B-doped Cz cell gave an efficiency of 17%, which is ˜0.3% better than the low-resistivity B-doped cells. In addition, the LID effect was substantially reduced with an efficiency loss of ≦0.6% absolute as opposed to 1.1% for the low-resistivity thick cells, resulting in the stabilized efficiency of 16.4%. The reduced LID effect is attributed to: 1) the reduction of B concentration in the higher resistivity material, resulting in fewer LID traps; and 2) higher diffusion length to thickness ratio due to thinner material, resulting in decreased sensitivity to loss in diffusion length. Thus, higher resistivity and thinner material provides another strategy for reducing LID in B-doped Cz cells.

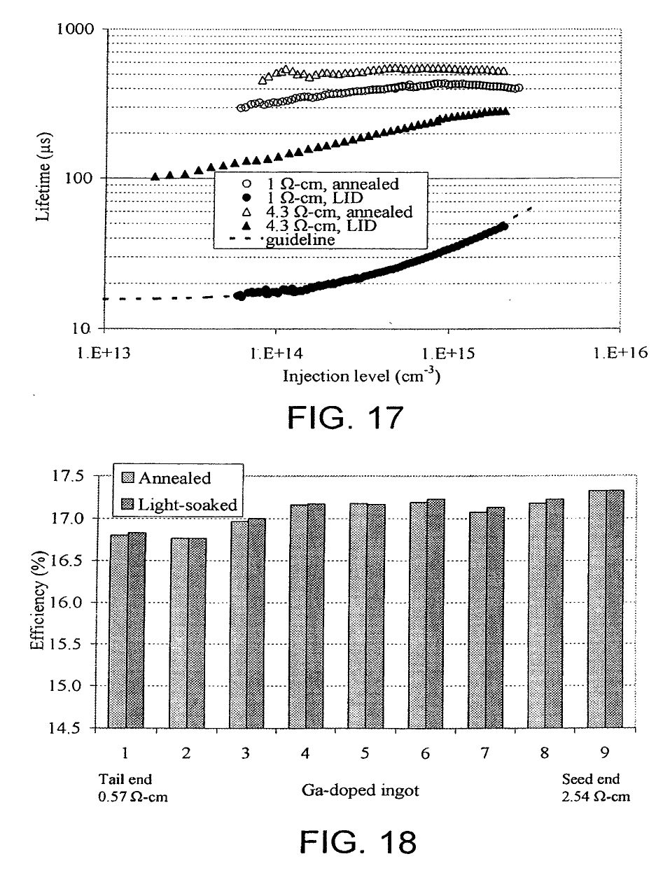

Device simulations were performed using PC1D program to establish that the impact of LID on the cell efficiency is entirely based on lifetime degradation at maximum power point (MPP). Some of the key inputs used for PC1D simulation are summarized in Table II. The simulated efficiency as a function of lifetime for a 300 μm thick 1.0 Ω-cm substrate and 230 μm thick 4.3 Ω-cm are plotted in FIG. 16. Due to a strong asymmetry of the capture time constants for electrons and holes (τₙ/τₚ˜0.1), specific for boron-oxygen-related recombination center, the bulk lifetime of a p-type material strongly depends on the injection level. This dependence of lifetime on injection level needs to be taken into account to assess the accurate and full impact of LID on cell efficiency. Therefore, first we measured the lifetime as a function of injection level in these samples as shown in FIG. 17. This was done on diffused samples after the emitter was removed. FIG. 17 confirms the asymmetric capture time constant because lifetime does vary strongly with injection level after LID. Notice that prior to LID, lifetime is high and is not a strong function of injection level.

This measured lifetime data was used in conjunction with PC1D calculation of efficiency as a function of lifetime (FIG. 16) to assess the loss in efficiency due to LID. To do this accurately, the loss in bulk lifetime was determined at the MPP. The device simulations were performed to determine the approximate injection level at the MPP in the 1 Ω-cm cells with 10-30 μs lifetime and in 4.3 Ω-cm cells with 80-200 μs lifetime. At the MPP, the injection level is not completely uniform along the device thickness. Carrier concentration profiles reveal that in the 1 Ω·cm cell, the injection level varied from 3×10¹² cm⁻³ to 1.2×10¹³ cm⁻³ at MPP for 10-30 μs bulk lifetime. FIG. 17 shows that in spite of this large variation in injection level, the lifetime should remain nearly at about 15 μs. Similarly for the 4.3 Ω-cm cell, the injection level at MPP was found to vary from 2.0×10¹³ cm⁻³ to 3.1×10¹³ cm⁻³ for 80 μs 200 μs bulk lifetime, resulting in a nearly constant lifetime of 105 μs at the MPP. These lifetime values were used in FIG. 16 to obtain the predicted cell efficiency after LID of 15.7% for 1.0 Ω-cm and 16.6% for 4.3 cells. These efficiencies were in good agreement with the experimental data in FIG. 15 (˜15.6% for 1.0 Ω-cm and 16.4% for 4.3 Ω-cm Cz). Note that in FIG. 16, if the measured lifetime at an injection level of 2×10¹⁴ cm⁻³ was used (which is closer to the V_{oc} condition of the cells), the simulation would have underestimated the LIT) effect on efficiency due to the strong lifetime dependence on injection level. FIG. 16 also shows that before LID, predicted efficiencies are ˜16.7% and ˜17.0% for 1.0 and 4.3 Ω-cm cells, which is again in good agreement with the experimental data even though the measured lifetime at 2×10¹⁴ cm⁻³ was used. This is because, prior to LID, measured lifetime is not a strong function of injection level. Thus, the LID effect can be predicted by simulation, by recognizing the strong injection level dependence of lifetime, and use the measured lifetime at the injection level around the peak power point. Lifetimes in solar cell materials are often measured at the V_{oc} condition or even at higher injection level (>1×10¹⁵ cm⁻³) to avoid trapping effects on lifetime data.

TABLE II
PC1D input parameters.

| Device Parameter | Input |
|---|---|
| Front surface | Textured, 54.74°, 3.535 μm |
| Front surface reflectance | From measurement |
| Broadband reflectance | 6.75-7.00% |
| Rear internal reflectance | 60%, diffuse |
| Base contact | 0.75-0.80 Ω |
| Internal conductor | 1 × 10⁻⁴ S |
| J₀₂ | 3.2-3.5 × 10⁻⁸ A |
| Front doping | 45 Ω/sq, Erfc |
| FSRV | 95,000-120,000 cm/s |
| BSRV | 750 cm/s for 1.0 Ω-cm |
| | 150 cm/s for 4.3 Ω-cm |

### Ga-Doped Ingot:

The variation in efficiency of the screen-printed Al-BSF solar cells fabricated on wafers from different ingot locations of Ga-doped ingot is plotted in FIG. 18. Both annealed (no LID) and light-soaked (after LID) states are included in FIG. 18.

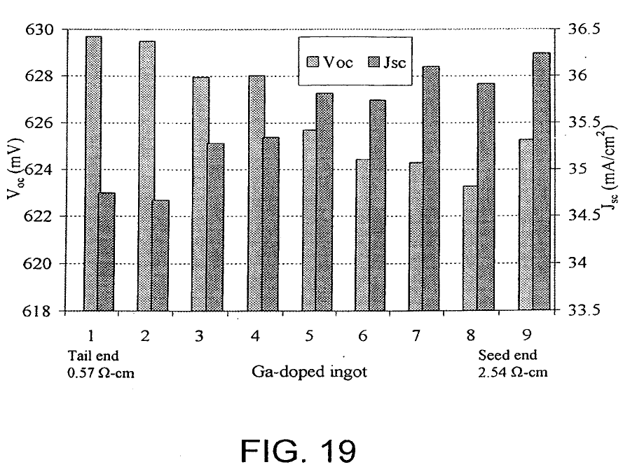

Unlike the B-doped ingots, the efficiency spread in Ga-doped ingot prior to the LID is somewhat larger (16.8%-17.3%), with the higher resistivity seed end producing slightly higher efficiency. This variation in efficiency is generally acceptable for production and is within the range of process-induced effects. Detailed analysis of cell parameters in FIG. 19 shows that, despite the very wide variation in resistivity over the entire length of the ingot, the spread in Ga-doped cell efficiency is reduced because of the increase in V_{oc} and the decrease in J_{sc} as the resistivity decreases. Moreover, there is essentially no LID observed in the Ga-doped cells, resulting in ˜1.5% higher absolute efficiency after light soaking relative to the low-resistivity B-doped Cz ingot. This gap in stabilized efficiency was reduced to ˜0.7% when higher resistivity and thin B-doped Cz was used. These results show that the Ga-doped Cz ingot offers great potential for higher stabilized Cz cell performance (≧17%). In addition, a high-quality Ga-doped ingot can be grown in the same puller used for the B-doped ingot, without any modification.

TABLE III
Summary of averaged efficiency from different Cz ingots.

| | | |
|---|---|---|
| Dopant | Resistivity | Efficiency (%) |

| Type | (Ω-cm) | Annealed | Stabilized |
|---|---|---|---|
| Boron | ~1.0 | 16.7 | 15.6 |
| | ~4.3 | 17.0 | 16.4 |
| Gallium | 0.57-2.54 | 17.1 | 17.1 |

Table III summarizes the average efficiency of solar cells from the three Cz Si ingots. These data demonstrate the potential of using Ga-doped Cz instead of B-doped Cz.

### CONCLUSION

This paper demonstrates the potential of using Ga dopant instead of B in p-type Cz Si to achieve high efficiency manufacturable screen-printed cells with no LID. Despite a large resistivity variation (0.57-2.54 Ω-cm) in the Ga-doped Cz ingot resulting from a small segregation coefficient of Ga in Si, the absolute efficiency of screen-printed Al-BSF solar cells was found to vary by <0.5% absolute over the entire length of the ingot. This is the result of the competing effect of increasing V_{oc} and decreasing J_{sc} as the resistivity decreases. In the 1 Ω-cm B-doped Cz, lifetimes decreased from 300-400 μs to ˜20 μs after LID. In the 4.3 Ω-cm, lifetimes decreased from 500 μs to 170 μs after LID. In the Ga-doped ingot, lifetimes were in the range of 100-1000 μs from seed to tail end, respectively, and showed no LID at all. This resulted in ˜1.5% higher average stabilized efficiency compared to the cells made on a 1 ohm-cm B-doped Cz and about 0.7% higher than efficiency with respect to 4.3 Ω-cm B-doped cells. These results were found to be in good agreement with device simulations performed using the measured lifetime at the injection level at MPP.

The use of thinner and high-resistivity B-doped Cz lessened the detrimental effect of LID. However, the LID remained appreciable and accounted for ˜0.6% absolute reduction in efficiency. Ga doping completely eliminated the Cz cells and gave ≧17% efficient screen-printed solar cells.

That which is claimed:

1. A method for fabricating a silicon solar cell structure comprising:
providing a gallium doped p-silicon substrate having a top-side and a back-side;
forming a n⁺ layer on the top-side of the gallium doped p-silicon substrate;
forming a silicon nitride AR layer on the top-side of the n⁺ layer;
forming Ag contacts on the silicon nitride anti-reflective (AR) layer using a screen-printing technique;
forming an Al contact layer on the back-side of the gallium doped p-silicon substrate using a screen-printing technique;
co-firing of the gallium doped p-silicon substrate having the n⁺-layer, silicon nitride AR layer, Ag metal contacts, and Al contact layer; and
forming a co-fired silicon solar cell structure, wherein the Ag contacts are in electrical communication with the n⁺ layer, wherein an Al back surface field layer (BSF) is formed, and wherein the silicon solar cell has a fill factor of about 0.75 to 0.85, a V_{oc} of about 550 to 650 mV, and a Jsc of about 28 to 36 mA/cm².

2. The method of claim 2, wherein forming the silicon solar cell structure includes a co-firing process; and wherein the co-firing process includes
heating the belt furnace at a rate of about 50 to 100° C./second to a temperature of about 700 to 900° C.;
holding the temperature in the belt furnace at about 700 to 900° C. for about 1 to 5 seconds; and
reducing the temperature in the belt furnace at a rate of about 50 to 100° C./second
